(19) United States
(12) Patent Application Publication
(10) Pub. No.: US 2024/0105602 A1
(43) Pub. Date: Mar. 28, 2024

(54) SEMICONDUCTOR DEVICE INCLUDING CONNECTION PORTION BETWEEN STACKED STRUCTURES AND METHOD OF FABRICATING THE SAME

(71) Applicant: SK hynix Inc., Gyeonggi-do (KR)

(72) Inventors: Mir IM, Gyeonggi-do (KR); Won Tae KOO, Gyeonggi-do (KR)

(21) Appl. No.: 18/192,643

(22) Filed: Mar. 30, 2023

(30) Foreign Application Priority Data
Sep. 28, 2022 (KR) 10-2022-0123452

(51) Int. Cl. H01L 23/528; H01L 23/522

(52) U.S. Cl. CPC H01L 23/5283; H01L 23/5226; H10B 43/20; H10B 43/35

(57) ABSTRACT

A semiconductor device according to an embodiment includes a first stacked structure including a first base body, a first connection pad disposed over a surface of the first base body, and a first pad buffer layer disposed adjacent to the first connection pad and the first pad buffer layer including an insulating material having a porous structure. In addition, the semiconductor device includes a second stacked structure including a second base body, a second connection pad disposed over a surface of the second base body, and a second pad buffer layer disposed adjacent to the second connection pad and the second pad buffer layer including an insulating material having a porous structure. The semiconductor device includes a connection portion of the first and second stacked structures that connects the first and second connection pads.

### CROSS-REFERENCE TO RELATED APPLICATIONS

The present application claims priority under 35 U.S.C. 119(a) to Korean Application No. 10-2022-0123452, filed on Sep. 28, 2022, which is incorporated herein by reference in its entirety.

### BACKGROUND

### 1. Technical Field

Various embodiments of the present disclosure generally relate to a semiconductor device and, more particularly, to a semiconductor device including a connection portion between stacked structures, and method of fabricating the same.

### 2. Related Art

Recently, as a method of fabricating a semiconductor device, a method of forming different integrated circuits on first and second substrates, and bonding the first and second substrates on which the integrated circuit are formed to connect the integrated circuits to each other has been proposed. As an example, the integrated circuits of the first and second substrates may be electrically connected to each other by bonding conductive pads of the first and second substrates to each other. In this case, the structural stability of the conductive pads of the first and second substrates may determine the electrical reliability of the semiconductor device.

### SUMMARY

A semiconductor device according to an embodiment of the present disclosure may include a first stacked structure that includes a first base body, a first connection pad disposed over a surface of the first base body, and a first pad buffer layer disposed adjacent to the first connection pad. The first pad buffer layer may include a first insulating material having a porous structure. In addition, the semiconductor device may include a second stacked structure that includes a second base body, a second connection pad disposed over a surface of the second base body, and a second pad buffer layer disposed adjacent to the second connection pad. The second pad buffer layer may include a second insulating material having a porous structure. The semiconductor device may include a connection portion of the first and second stacked structures that connects the first and second connection pads.

A semiconductor device according to another embodiment of the present disclosure may include a first substrate structure that includes a substrate, a memory cell driver circuit disposed over the substrate, a first connection pad disposed over the substrate to be electrically connected to the memory cell driver circuit, and a first pad buffer layer disposed in a lateral direction of the first connection pad. The first pad buffer layer may include a first insulating material having a porous structure. In addition, the semiconductor device may include a second substrate structure that includes a substrate, a memory cell structure disposed over the substrate, a second connection pad disposed over the substrate to be electrically connected to the memory cell structure, and a second pad buffer layer disposed in a lateral direction of the second connection pad. The second pad buffer layer may include a second insulating material having a porous structure. In addition, the semiconductor device may include a connection portion of the first and second substrate structures that connects the first and second connection pads.

There is disclosed a method of fabricating a semiconductor device. In the method, a first substrate structure that includes a substrate, a first connection pad disposed over a surface of the first substrate, and a first pad buffer layer disposed adjacent to the first connection pad may be formed. The first pad buffer layer may include a metal-organic framework. A second substrate structure that includes a substrate, a second connection pad disposed over a surface of the second substrate, and a second pad buffer layer disposed adjacent to the second connection pad may be formed. The second pad buffer layer may include a metal-organic framework. The first and second substrate structures may be bonded to each other to form a connection portion of the first and second connection pads.

A semiconductor device according to another embodiment of the present disclosure may include a first substrate structure that includes a first connection pad and a first pad buffer layer disposed to surround at least a sidewall of the first connection pad. In addition, the semiconductor device may include a second substrate structure that includes a second connection pad and a second pad buffer layer disposed to surround at least a sidewall of the second connection pad. The first and second substrate structures are physically and electrically bonded to each other using the first and second connection pads. The first and second pad buffer layers include an insulating material having a porous structure.

### BRIEF DESCRIPTION OF THE DRAWINGS

FIG. 1 is a cross-sectional view schematically illustrating a semiconductor device according to an embodiment of the present disclosure.

FIG. 2A is a plan view schematically illustrating a metal-organic framework according to an embodiment of the present disclosure.

FIG. 2B is a cross-sectional view schematically illustrating a stack of a plurality of metal-organic frameworks according to an embodiment of the present disclosure.

FIG. 3 is a cross-sectional view schematically illustrating a semiconductor device according to another embodiment of the present disclosure.

FIG. 4 is a cross-sectional view schematically illustrating a semiconductor device according to another embodiment of the present disclosure.

FIGS. 5 to 16 are cross-sectional views schematically illustrating a method of fabricating a semiconductor device according to an embodiment of the present disclosure.

FIGS. 17 to 28 are cross-sectional views schematically illustrating a method of fabricating a semiconductor device according to another embodiment of the present disclosure.

FIGS. 29, 30, 31A, and 31B are cross-sectional views schematically illustrating a method of fabricating a semiconductor device, and a semiconductor device fabricated by the method according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise,” “include,” or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Further, in performing a method or a fabricating method, each process constituting the method can take place differently from the stipulated order unless a specific sequence is described explicitly in the context. In other words, each process may be performed in the same manner as stated order, and may be performed substantially at the same time. Also, at least a part of each of the above processes may be performed in a reversed order.

A two-dimensional material disclosed herein may refer to a crystalline material in which atoms or molecules are formed as a single monolayer. The single monolayer may have, for example, a form of a sheet having a two-dimensional structure having a flat surface. In the single monolayer of the two-dimensional material, the atoms or molecules may be bound by an intramolecular force such as a covalent bond. The single monolayer may be stacked into a plurality of layers by being bound to another adjacent layer by an intermolecular force such as a van der Waals force. Accordingly, the two-dimensional material stacked in the plurality of layers may form a thin film having a three-dimensional structure.

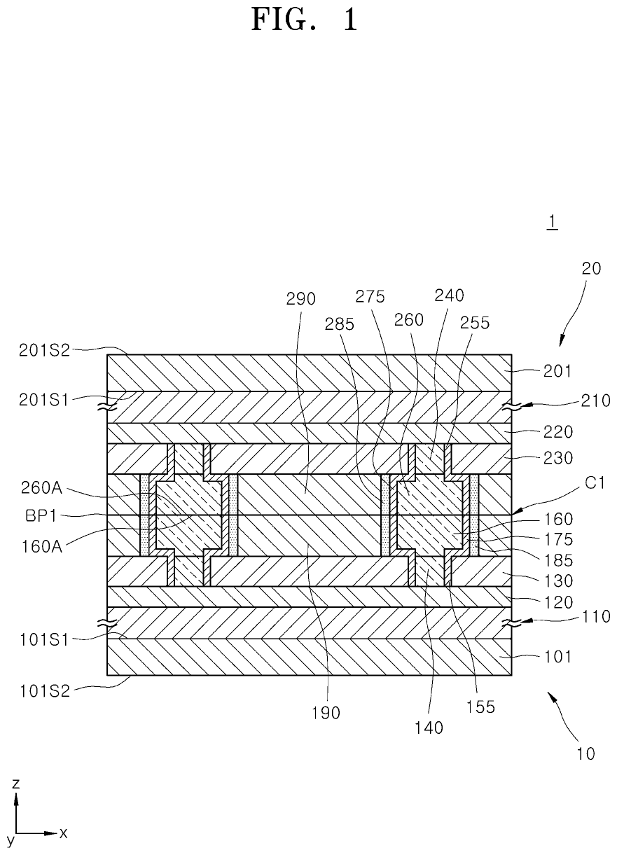

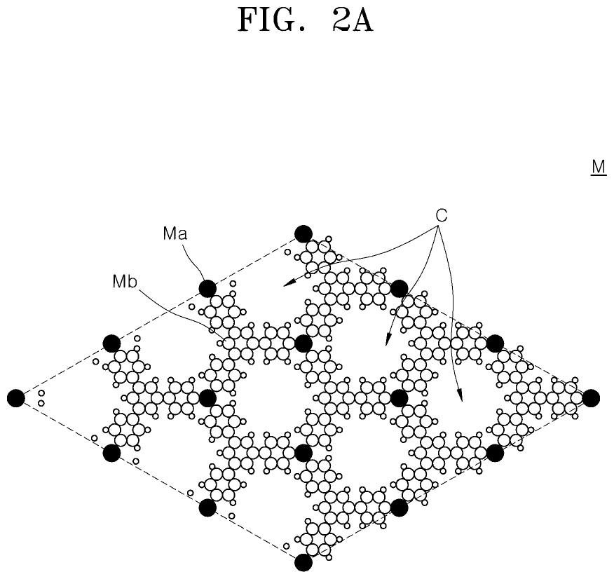

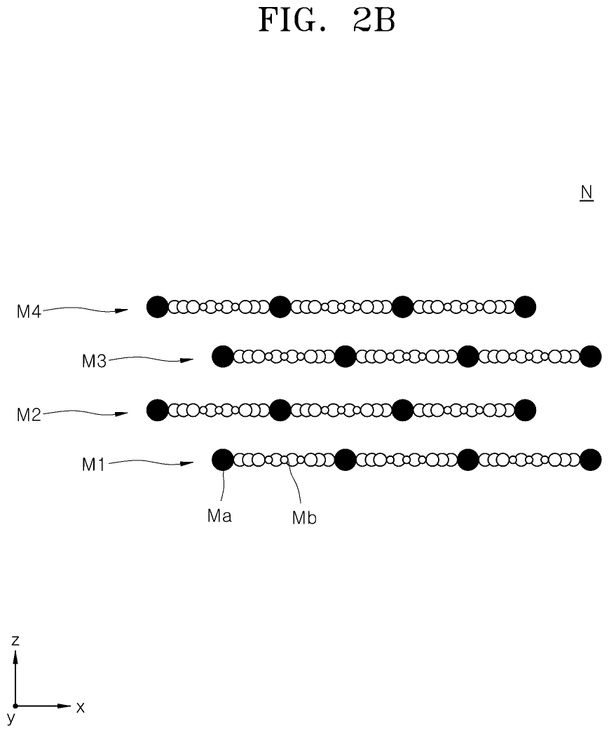

FIG. 1 is a cross-sectional view schematically illustrating a semiconductor device according to an embodiment of the present disclosure. FIG. 2A is a plan view schematically illustrating a metal-organic framework according to an embodiment of the present disclosure. FIG. 2B is a cross-sectional view schematically illustrating a stack of a plurality of metal-organic frameworks according to an embodiment of the present disclosure.

Referring to FIG. 1, the semiconductor device 1 may include a first stacked structure 10, a second stacked structure 20, and a connection portion C1. The connection portion C1 may connect the first and second stacked structures 10 and 20 to each other. Through the connection portion C1, the first and second stacked structures 10 and 20 may be physically bonded to each other and may be electrically connected to each other.

The first stacked structure 10 may include a first base body 101, first connection pads 160 disposed over a first surface 101S1 of the first base body 101, and first pad buffer layers 185 disposed adjacent to the first connection pads 160. In addition, the first stacked structure 10 may further include first pad barrier layers 175 disposed between the first connection pads 160 and the first pad buffer layers 185. In addition, the first stacked structure 10 may further include a first bonding dielectric layer 190 disposed adjacent to the first connection pads 160 in a lateral direction (e.g., an x-direction). The lateral direction in the first stacked structure 10 may mean a direction that is substantially parallel with a first surface 101S1 of the first base body 101. In an embodiment, the first bonding dielectric layer 190 may be disposed to contact the first pad buffer layers 185 in the lateral direction.

Referring to FIG. 1, the first base body 101 may support the first stacked structure 10. The first base body 101 may be, for example, a substrate or a thin film structure. The first base body 101 may include, for example, a semiconductor material, a conductive material, or an insulative material.

In an embodiment, the first base body 101 may be a semiconductor substrate. The first base body 101 may include the first surface 101S1 and a second surface 101S2 opposite to the first surface 101S1. The base body 101 may include a doped well region (not shown). The doped well region may be formed in an active region (not shown) that may be an inner region adjacent to the first surface 10151.

A first device structure layer 110 may be disposed on the first surface 10151 of the first base body 101. Although not shown in FIG. 1, the first device structure layer 110 may include electronic devices that are electrically connected to the doped well region of the first base body 101. The electronic devices may include, for example, a field effect transistor (FET), a capacitor, and the like. In an embodiment, the first device structure layer 110 may be formed through a front end of line (FEOL) process of a semiconductor device fabrication process. The first device structure layer 110 may include a plurality of conductive layers and insulating layers disposed between the plurality of conductive layers.

A metal wiring layer 120 may be disposed on the first device structure layer 110. Although not shown, the metal wiring layer 120 may electrically connect the electronic devices of the first device structure layer 110 to each other. The metal wiring layer 120 may electrically connect the electronic devices to the first base body 101.

The metal wiring layer 120 may be made of any suitable material including, for example, aluminum (Al), copper (Cu), tungsten (W), titanium (Ti), tantalum (Ta), or any combination thereof. In an embodiment, the metal wiring layer 120 may be formed through a back end of line (BEOL) process of a semiconductor device fabrication process.

A base buffer layer 130 may be disposed on the metal wiring layer 120. The base buffer layer 130 may be disposed between the metal wiring layer 120 and the first connection pad 160 in a vertical direction (e.g., a z-direction). Vias 140 may be disposed in the base buffer layer 130. Each of the vias 140 may be formed in a via hole penetrating the base buffer layer 130. In an embodiment, the vias 140 may electrically connect the metal wiring layer 120 to the first connection pad 160. In an embodiment, the vias 140 may be disposed to directly contact the metal wiring layer 120.

Each of the vias 140 may be made of any suitable material including, for example, aluminum (Al), copper (Cu), tungsten (W), titanium (Ti), tantalum (Ta), or any combination thereof. For example, each of the vias 140 may be formed of substantially the same material used to form the metal wiring layer 120.

In an embodiment, the base buffer layer 130 may include an insulating material having a porous structure. The insulating material having the porous structure may include voids or cavities inside the insulating material. In an embodiment, the insulating material having the porous structure may include a metal-organic framework as described with FIGS. 2A and 2B. The metal-organic framework may have a two-dimensional structure or a three-dimensional structure. The metal-organic framework may have electrical insulation.

Referring to FIG. 2A, a metal-organic framework M having a two-dimensional structure is disclosed according to an embodiment of the present invention. The metal-organic framework M may be a material formed by coordination between metal-containing nodes Ma and organic ligands Mb. The nodes Ma including metal may include, for example, metal ions or metal clusters. The metal of the node Ma may include, for example, zinc (Zn), chromium (Cr), indium (In), gallium (Ga), copper (Cu), iron (Fe), molybdenum (Mo), cobalt (Co), ruthenium (Ru), manganese (Mn), lanthanum (La), titanium (Ti), hafnium (Hf), cadmium (Cd), zirconium (Zr), and the like. The organic ligand Mb may include, for example, oxalic acid, fumaric acid, benzenehexathiol, triphenylenehexathiol, 1,4-benzene dicarboxylic acid (1-4, benzene dicarboxylic acid), hexaaminobenzene, tetrakis (4-carboxyphenyl)-porphyrinato-cobalt (II), tetrakis (4-carboxyphenyl)-porphyrin), and the like. As another example, the organic ligand Mb may include H₂BDC (1,4-benzenedicarboxylic acid), H₂BDC-Br, H₂BDC-OH, H₂BDC-NO2, H₂BDC-NH₂, H₄DOT, H₂BDC-(Me)₂, H₂BDC-(Cl)₂, and the like.

Referring to FIG. 2A, the metal-organic framework M may have a porous structure having cavities C therein. In an embodiment, the metal-organic framework M may have a physically and chemically stable two-dimensional mesh bonding structure as shown in FIG. 2A. As shown in FIG. 2A, in the metal-organic framework M, coordination bonds between the metal-containing nodes Ma and the organic ligands Mb may be regularly formed in two dimensions. As a result, the metal-organic framework M may have a thickness of a nano size (e.g., 1 nm to 100 nm) corresponding to a single monolayer of atoms or molecules. The metal-organic framework M may have a form of a sheet.

Referring to FIG. 2B, there is disclosed a metal-organic framework layer N. In an embodiment, the metal-organic framework layer N may have a two-dimensional structure in which the metal-organic frameworks M1, M2, M3, and M4 are stacked in a thickness direction (i.e., the z-direction). Each of a plurality of metal-organic frameworks M1, M2, M3, and M4 may have a form of a sheet. Each of the plurality of metal-organic frameworks M1, M2, M3, and M4 may be combined with each other by a van der Waals force acting in a direction perpendicular to a surface of the sheet (i.e., the z-direction), thereby forming a thin film in which the sheets are stacked. In FIG. 2B, as an embodiment, the metal-organic framework layer N is illustrated to have a form in which four metal-organic frameworks M1, M2, M3, and M4 are stacked, but is not necessarily limited thereto. In some embodiments, the metal-organic framework layer N may have a form in which various other numbers of metal-organic structure layers N are stacked.

In embodiments different from the embodiments of FIGS. 2A and 2B, in the metal-organic framework, the nodes Ma including metal and the organic ligands Mb may be coordinated in a three-dimensional structure. In this case, the metal-organic framework may have cavities in three-dimensional spaces.

Referring to FIG. 1, in an embodiment, the base buffer layer 130 may serve to relieve stress generated in a lateral direction (e.g., the x-direction or the y-direction) by the thermally expanded vias 140 when the vias 140 are thermally expanded. As described above, because each of the vias 140 includes metal, the via 140 may have a higher thermal expansion coefficient compared to the insulating layers positioned in the lateral direction. As will be described later, the vias 140 may be thermally expanded by heat applied during a bonding process of the first and second stacked structures 10 and 20.

According to an embodiment of the present disclosure, the base buffer layer 130 may include the metal-organic framework including cavities. Accordingly, when a stress corresponding to the amount of deformation of the vias 140 expanding in the lateral direction is applied, the base buffer layer 130 may absorb the stress using the cavities. As a result, when the vias 140 are disposed adjacent to the base buffer layer 130, the structural stability of the vias 140 may be improved.

In an embodiment, referring to FIG. 1, at least a portion of the base buffer layer 130 may overlap with the first connection pads 160 in the z-direction. Accordingly, when the first connection pads 160 are thermally expanded in a substrate 101 direction (i.e., the z-direction), the base buffer layer 130 may serve to relieve the stress generated in the substrate 101 direction due to the thermal expansion.

In an embodiment, the metal-organic framework having the porous structure may have low permittivity. As an example, the permittivity of the metal-organic framework may be lower than that of silicon oxide. As an example, a dielectric constant K of the metal-organic framework may be 2 or less. Accordingly, the RC delay occurring between the plurality of circuit pattern layers disposed with the base buffer layer 130 therebetween may be reduced.

Referring to FIG. 1, a via barrier layer 155 may be disposed between each of the vias 140 and the base buffer layer 130 in a lateral direction (e.g., the x-direction). The via barrier layer 155 may be disposed to surround the vias 140.

In an embodiment, the via barrier layer 155 may include a two-dimensional material. For example, the two-dimensional material may include MXene. In an embodiment, the via barrier layer 155 may include at least one layer of the MXene. MXene may have electrical conductivity.

In an embodiment, MXene may have a chemical formula of Mₙ₊₁Xₙ. In this case, n may be 1, 2, or 3, and M may include scandium (Sc), titanium (Ti), zirconium (Zr), hafnium (Hf), vanadium (V), niobium (Nb), tantalum (Ta), chromium (Cr), molybdenum (Mo), tungsten (W), or any combination thereof. X may include carbon (C), nitrogen (N), or any combination thereof. That is, the MXene may include, for example, transition metal carbide, transition metal nitride, or transition metal carbonitride. The MXene may have crystallinity in a two-dimensional plane, based on the above chemical formula.

In an embodiment, because the MXene has the two-dimensional structure, MXene may have a flat surface. Accordingly, it is possible to prevent in-elastic scattering at an interface between the via 140 and the via barrier layer 155 when electrons moving in the z-direction inside the vias 140 collide each other at the interface. As a result, electrical mobility of the electrons along the z-direction within the vias 140 may be improved. As such, the via barrier layer 155 including the MXene may function as a liner layer disposed on sidewalls of the vias 140.

In an embodiment, the via barrier layer 155 may function as a barrier layer that prevents metal inside the vias 140 from moving to the base buffer layer 130. In an embodiment, when the via barrier layer 155 includes a crystalline two-dimensional material, diffusion of the metal of the vias 140 through the via barrier layer 155 to the base buffer layer 130 may be effectively prevented. In an embodiment, when the via barrier layer 155 includes a stacked structure of the two-dimensional material, the via barrier layer 155 may maintain crystallinity at a thickness thinner than that of the conventional via barrier layer that does not employ the two-dimensional material. Accordingly, the via barrier layer 155 may be controlled to have a thickness thinner than that of the conventional via barrier layer.

Referring to FIG. 1, the first connection pads 160 may be disposed over the base buffer layer 130 to be electrically connected to the vias 140. Each of the first connection pads 160 may include, for example, aluminum (Al), copper (Cu), tungsten (W), titanium (Ti), tantalum (Ta), or any combination thereof. The first connection pads 160 may be electrically bonded to second connection pads 260 of the second stacked structure 20. The first and second connection pads 160 and 260 may form the connection portion C1 of the semiconductor device 1. In the connection portion C1, each of the first connection pads 160 may have a first surface area 160A.

Referring to FIG. 1, the first pad buffer layer 185 may be disposed adjacent to the first connection pads 160. The first pad barrier layer 175 may be disposed between each of the first connection pads 160 and the first pad buffer layer 185.

In an embodiment, the first pad buffer layer 185 may include an insulating material having a porous structure. In an embodiment, the insulating material may include a metal-organic framework. The metal-organic framework may have a two-dimensional structure or a three-dimensional structure. The metal-organic framework may be substantially the same as the metal-organic framework M described above with reference to FIG. 2A. The first pad buffer layer 185 may include a metal-organic framework layer N in which the plurality of metal-organic frameworks M described above with reference to FIG. 2B are stacked.

In an embodiment, the first pad buffer layer 185 may serve to relieve stress generated in the lateral direction (e.g., the x-direction or the y-direction) by the thermally expanding first connection pads 160 when the first connection pads 160 including metal thermally expands. That is, the function substantially the same as the function performed by the base buffer layer 130 with respect to the vias 140 may be performed by the first pad buffer layer 185 with respect to the first connection pads 160. As a result, the structural stability of the first connection pads 160 between the first connection pads 160 and the first pad buffer layer 185 may be improved. In an embodiment, the insulating material having a porous structure may have low permittivity. Accordingly, the RC delay between a plurality of circuit pattern layers disposed with the first pad buffer layer 185 interposed therebetween may be reduced.

In an embodiment, the first pad barrier layer 175 may be disposed to surround the first connection pads 160. In an embodiment, the first pad barrier layer 175 may include a two-dimensional material. For example, the two-dimensional material may include MXene. In an embodiment, the first pad barrier layer 175 may include at least one layer of MXene. MXene may have electrical conductivity.

In an embodiment, the first pad barrier layer 175 may perform the same function with respect to the first connection pads 160 as the function performed by the first via barrier layer 155 with respect to the vias 140. As an example, the first pad barrier layer 175 may function as a liner layer disposed on sidewalls of the first connection pads 160. As another example, the first pad barrier layer 175 may function as a barrier layer that prevents the metal inside the first connection pads 160 from moving to the first pad buffer layer 185.

The first pad barrier layer 175 may include the two-dimensional material having crystallinity to be controlled to have a thickness thinner than that of the conventional pad barrier layer that does not include the two-dimensional material.

Referring to FIG. 1, the first bonding dielectric layer 190 may be disposed adjacent to the first pad buffer layer 185 in a lateral direction (e.g., the x-direction or the y-direction). Specifically, the first bonding dielectric layer 190 may be disposed to contact the first pad buffer layer 185. The first bonding dielectric layer 190 may include, for example, oxide, nitride, or oxynitride. The first bonding dielectric layer 190 may be bonded to a second bonding dielectric layer 290 of the second stacked structure 20 to form the connection portion C1 of the semiconductor device 1.

Referring to FIG. 1, the second stacked structure 20 may be disposed over the first stacked structure 10. The second stacked structure 20 may include a second base body 201 including a first surface 201S1 and a second surface 201S2 opposite to the first surface 201S1. In the description of the second stacked structure 20 below, expressions of “on” and “over” are expressions of a relative concept based on the first surface 201S1 and the second surface 201S2, and might not necessarily coincide with the upper side in the drawings. The second stacked structure 20 may include second connection pads 260 disposed over the first surface 201S1 of the second base body 201, and a second pad buffer layer 285 disposed adjacent to the second connection pads 260. In addition, the second stacked structure may further include a second pad barrier layer 275 disposed between the second connection pads 260 and the second pad buffer layer 285. In addition, the second stacked structure 20 may further include the second bonding dielectric layer 290 disposed adjacent to the second connection pads 260 in a lateral direction (e.g., the x-direction). The lateral direction in the second stacked structure 20 may mean a direction that is substantially parallel with a first surface 201S1 of the second base body 201. In an embodiment, the second bonding dielectric layer 290 may be disposed to contact the second pad buffer layer 285 in the lateral direction.

In addition, the second stacked structure 20 may further include a second device structure layer 210, a metal wiring layer 220, a base buffer layer 230, vias 240, and a via barrier layer 255 which are disposed between the second base body 201 and the second connection pads 260. Specifically, the second device structure layer 210 may be disposed on the first surface 201S of the second base body 201. The metal wiring layer 220 may be disposed on the second device structure layer 210, and the base buffer layer 230 may be disposed on the metal wring layer 220. The base buffer layer 230 may be disposed between the metal wiring layer 220 and the second connection pad 260 in a vertical direction (e.g., the z-direction). The vias 240 may be disposed inside the base buffer layer 230 and may electrically connect the metal wiring layer 220 to the second connection pads 260. The via barrier layer 255 may be disposed between the vias 240 and the base buffer layer 230.

In an embodiment, a configuration of the second stacked structure 20 may be substantially the same as a configuration of the first stacked structure 10. As an example, the second base body 201, the second connection pads 260, and the second pad buffer layer 285 of the second stacked structure 20 may be substantially the same as the first base body 101, the first connection pads 160, and the first pad buffer layer 185 of the first stacked structure 10, respectively. In addition, the second device structure layer 210, the metal wiring layer 220, the base buffer layer 230, the vias 240, the via barrier layer 255, the second pad barrier layer 275, and the second bonding dielectric layer 290 of the second stacked structure 20 may be substantially the same as the first device structure layer 110, the metal wiring layer 120, the first base buffer layer 130, the vias 140, the via barrier layer 155, the first pad barrier layer 175, and the first bonding dielectric layer 190 of the first stacked structure 10, respectively.

In an embodiment, each of the base buffer layer 130 and the first pad buffer layer 185 of the first stacked structure 10 may include the metal-organic framework including cavities. Similarly, each of the base buffer layer 230 and the second pad buffer layer 285 of the second stacked structure 20 may include the metal-organic framework including cavities.

In another embodiment, one of the base buffer layer 130 and the first pad buffer layer 185 of the first stacked structure 10 may include the metal-organic framework including cavities, and the other may include an insulating material other than the metal-organic framework. Similarly, one of the base buffer layer 230 and the second pad buffer layer 285 of the second stacked structure 20 may include the metal-organic framework including cavities, and the other may include an insulating material other than the metal-organic framework. In this case, the insulating material of each of the first and second stacked structures 10 and 20 may include, for example, oxide, nitride, oxynitride, or a combination thereof. In an embodiment, the insulating materials of the first and second stacked structures 10 and 20 may have a porous structure.

Referring to FIG. 1, there is provided the connection portion C1 of the first stacked structure 10 and the second stacked structure 20. The connection portion C1 may include a bonding surface BP1 of the first and second stacked structures 10 and 20. In an embodiment, on the bonding surface BP1, bonding of the first connection pad 160 and the second connection pad 260, and bonding of the first bonding dielectric layer 190 and the second bonding dielectric layer 290 may be formed. In an embodiment, on the bonding surface BP1, contact between the first pad barrier layer 175 and the second pad barrier layer 275 and contact between the first pad buffer layer 185 and the second pad buffer layer 285 may occur.

In an embodiment, in the connection portion C1, a surface area 160A of the first connection pad 160 and a surface area 260A of the second connection pad 260 may be substantially the same.

Accordingly, the first and second connection pads 160 and 260 may be disposed to align with each other. In an embodiment, the first and second connection pads 160 and 260 may overlap with each other.

As described above, in the semiconductor device 1, the first and second stacked structures 10 and 20 may be bonded to each other through the connection portion C1. The first and second connection pads 160 and 260 of the connection portion C1 may be bonded to each other, so that the first and second stacked structures 10 and 20 may be electrically connected to each other. In addition, the semiconductor device 1 may further include bonding of the first and second bonding dielectric layers 190 and 290 in the connection portion C1.

In an embodiment, each of the first and second stacked structures 10 and 20 of the semiconductor device 1 may include the first and second pad buffer layers 185 ad 285 each including an insulating material having a porous structure and the first and second pad barrier layers 175 and 275 each including a two-dimensional material, respectively. In addition, the first and second stacked structures 10 and 20 of the semiconductor device 1 may include the base buffer layers 130 and 230, the vias 140 and 240, and the via barrier layers 155 and 255 which are spaced apart from the connection portion C1, respectively. Each of the base buffer layers 130 and 230 may include an insulating material having a porous structure. Through the above-described configuration, it is possible to provide the semiconductor device 1 that includes the connection portion C1 having improved structural and electrical reliability when the first and second stacked structures 10 and 20 are bonded.

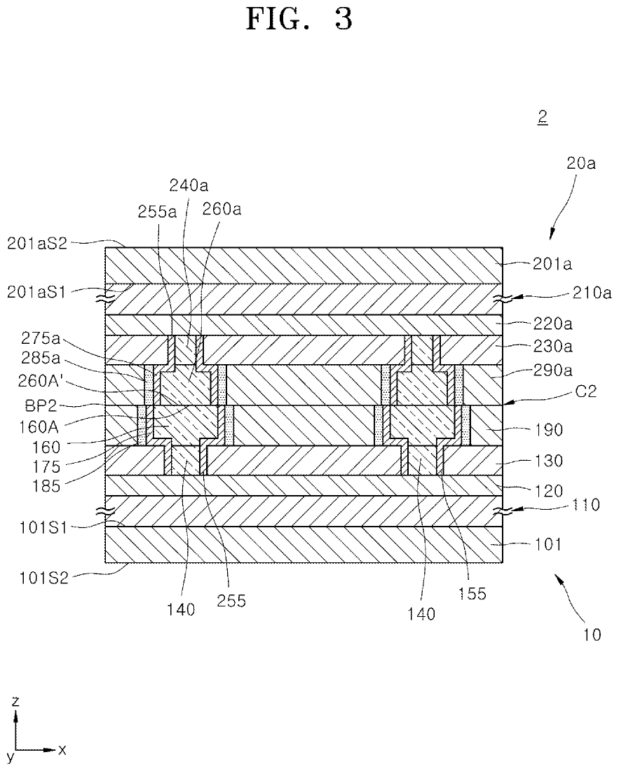

FIG. 3 is a cross-sectional view schematically illustrating a semiconductor device 2 according to another embodiment of the present disclosure. Referring to FIG. 3, the semiconductor device 2 may include a first stacked structure 10, a second stacked structure 20a, and a connection portion C2 between the first and second stacked structures 10 and 20a. The connection portion C2 may connect the first and second stacked structures 10 and 20a to each other. Through the connection portion C2, the first and second stacked structure 10 and 20a may be physically bonded to each other and may be electrically connected to each other.

Referring to FIG. 3, the semiconductor device 2 may be different from the semiconductor device 1 of FIG. 1 in a configuration of a second connection pad 260a of the second stacked structure 20a.

Other components of the second stacked structure 20a except for the second connection pads 260a, for example, a second base body 201a having first and second surfaces 201aS1 and 201aS2, a second device structure layer 210a, a metal wiring layer 220a, a base buffer layer 230a, vias 240a, a via barrier layer 255a, a second pad barrier layer 275a, and a second pad buffer layer 285a may be substantially the same as the second base body 201 having the first and second surfaces 201S1 and 201S2, the second device structure layer 210, the metal wiring layer 220, the base buffer layer 230, the vias 240, the via barrier layer 255, the second pad barrier layer 275, and the second pad buffer layer 285 of the semiconductor device 1 described with reference to FIG. 1, respectively.

Referring to FIG. 3, in the connection portion C2, a surface area 260A′ of the second connection pad 260a may be smaller than a surface area 160A of a first connection pad 160. Accordingly, even when misalignment occurs between the first connection pads 160 and the second connection pads 260a in the connection portion C2, the possibility that an electrical connection failure occurs between the first and second connection pads 160 and 260a may be reduced.

Referring to FIG. 3, on a bonding surface BP2 of the connection portion C2, bonding of the first connection pads 160 and the second connection pads 260a and bonding of a first bonding dielectric layer 190 and a second bonding dielectric layer 290a may be formed. In addition, on the bonding surface BP2, contact between the first connection pads 160 and the second pad barrier layer 275a, contact between the first pad barrier layer 175 and the second pad buffer layer 285a, and contact between the first pad buffer layer 185 and the second bonding dielectric layer 290 may additionally occur.

In FIG. 3, an embodiment in which the surface area 260A′ of the second connection pad 260a in the connection portion C2 is smaller than the surface area 160A of the first connection pad 160 is disclosed, but the present disclosure may not be limited thereto. In other embodiments not shown, the second connection pads 260a may be formed such that the surface area 260A′ of the second connection pad 260a is greater than the surface area 160A of the first connection pad 160.

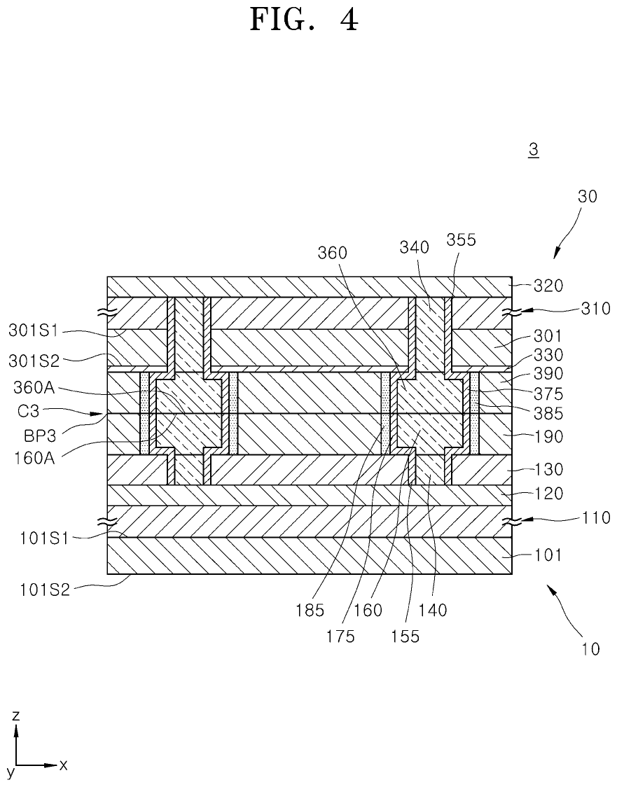

FIG. 4 is a cross-sectional view schematically illustrating a semiconductor device 3 according to another embodiment of the present disclosure. Referring to FIG. 4, the semiconductor device 3 may include a first stacked structure 10, a second stacked structure 30, and a connection portion C3 between the first and second stacked structures 10 and 30. The connection portion C3 may connect the first and second stacked structures 10 and 30 to each other. Through the connection portion C3, the first and second stacked structures 10 and may be both physically and electrically connected to each other. Referring to FIG. 4, the semiconductor device 3 may be different from the semiconductor device 1 of FIG. 1 in a configuration of the second stacked structure 30.

The second stacked structure 30 may include a second base body 301 including a first surface 301S1 and a second surface 301S2. The second base body 301 may include a doped well region formed in an active region that is an inner region adjacent to the first surface 301S1. In the description of the second stacked structure 30 below, expressions of “on” and “over” are expressions of a relative concept based on the first surface 301S1 and the second surface 301S2, and might not necessarily coincide with the upper side in the drawings.

A second device structure layer 310 may be disposed on the first surface 301S1 of the second base body 301. The second device structure layer 310 may include electronic devices that are electrically connected to the doped well region of the second base body 301.

A metal wiring layer 320 may be disposed on the second device structure layer 310. Although not shown, the metal wiring layer 320 may electrically connect the electronic devices in the second device structure layer 310 to each other.

Referring to FIG. 4, a base buffer layer 330 may be disposed on the second surface 301S2 of the second base body 301. The base buffer layer 330 may include an insulating material having porosity. In an embodiment, the base buffer layer 330 may include a metal-organic framework layer. The material of the base buffer layer 330 may be substantially the same as the material of the base buffer layer 230 of the semiconductor device 1 described above with reference to FIG. 1.

Referring to FIG. 4, through vias 340 may be disposed in the base buffer layer 330, the second base body 301, and the second device structure layer 310. The through vias 340 may be electrically connected to the metal wiring layer 320. A via barrier layer 355 may be disposed between the through vias 340 and the base buffer layer 330, between the through vias 340 and the second base body 301, and between the through vias 340 and the second device structure layer 310. The materials of each of the through via 340 and the via barrier layer 355 may be substantially the same as the materials of the via 240 and the via barrier layer 255 of the semiconductor device 1 described with reference to FIG. 1, respectively.

Referring to FIG. 4, second connection pads 360 may be disposed on the second surface 301S2 of the second base body 301, specifically, on the base buffer layer 330. The second connection pad 360 may be electrically connected to the through via 340. A second pad buffer layer 385 may be disposed adjacent to the second connection pads 360. In addition, a second pad barrier layer 375 may be disposed between the second connection pads 360 and the second pad buffer layer 385. In addition, a second bonding dielectric layer 390 may be disposed adjacent to the second pad buffer layer 385 in a lateral direction (e.g., the x-direction). The lateral direction in the second stacked structure 30 may mean a direction that is substantially parallel with a second surface 301S2 of the second base body 301. The materials of the second connection pad 360, the second pad barrier layer 375, the second pad buffer layer 385, and the second bonding dielectric layer 390 may be substantially the same as the materials of the second connection pad 260, the second pad barrier layer 275, the second pad buffer layer 285, and the second bonding dielectric layer 290 of the semiconductor device 1 described with reference to FIG. 1, respectively.

Referring to FIG. 4, the connection portion C3 of the semiconductor device 3 may include a bonding surface BP3 of the first and second stacked structures 10 and 30. In an embodiment, in the bonding surface BP3, bonding of the first connection pads 160 and the second connection pads 360 and bonding of the first bonding dielectric layer 190 and the second bonding dielectric layer 390 may be formed. In an embodiment, in the connection portion C3, a surface area 160A of the first connection pad 160 and a surface area 360A of the second connection pad 360 may be substantially the same as each other. Accordingly, the first and second connection pads 160 and 360 may be disposed to align with each other. Stated differently the first and second connection pads 160 and 360 are coextensive in the X direction. In an embodiment, the first and second connection pads 160 and 360 may overlap with each other.

In some other embodiments not shown, in the connection portion C3, the surface area 160A of the first connection pad 160 and the surface area 360A of the second connection pad 360 may be different from each other. In this case, in the connection portion C3, configurations of the first and second connection pads 160 and 360, the first and second pad barrier layers 175 and 375, the first and second pad buffer layers 185 and 385, and the first and second bonding dielectric layers 190 and 390 may be substantially the same as the configurations of the first and second connection pads 160 and 260a, the first and second pad barrier layers 175 and 275a, the first and second pad buffer layers 185 and 285a, and the first and second bonding dielectric layers 190 and 290a in the connection portion C2 of FIG. 3, respectively.

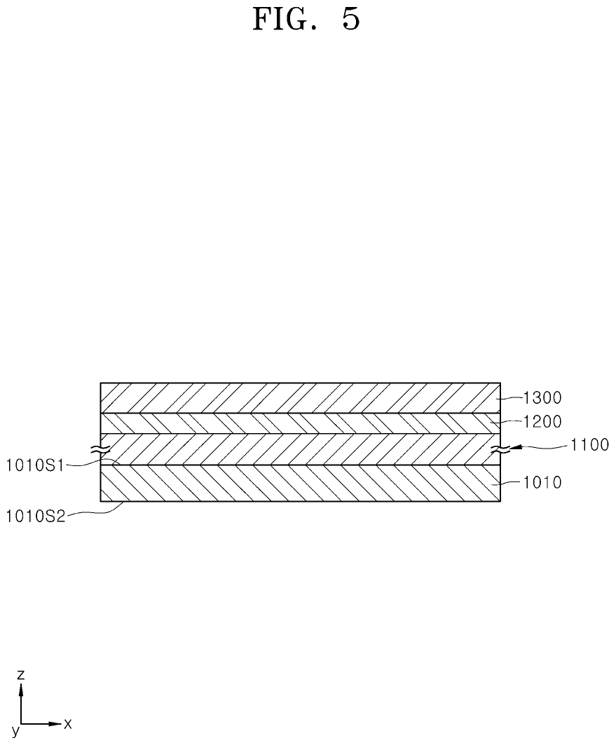

FIGS. 5 to 16 are cross-sectional views schematically illustrating a method of fabricating a semiconductor device according to an embodiment of the present disclosure. The method shown in FIGS. 5 to 16 may be applied to a method of fabricating the semiconductor device 1 described above with reference to FIG. 1.

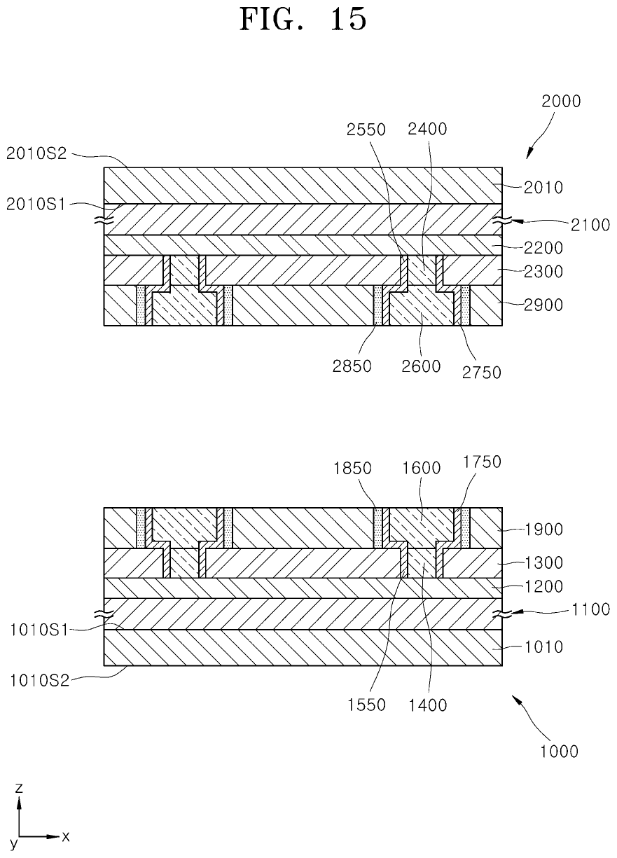

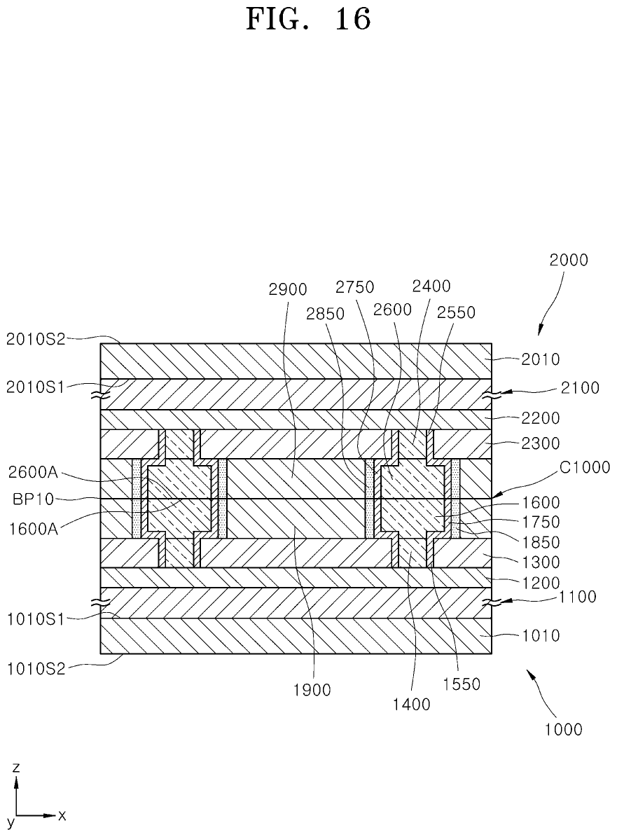

In an embodiment, the method of fabricating the semiconductor device may include a process of forming first and second substrate structures 1000 and 2000 by performing processes related to FIGS. 5 to 14, and a process of bonding the first and second substrate structures 1000 and 2000 by performing processes related to FIGS. 15 and 16.

First, the process of forming the first substrate structure 1000 will be described. Referring to FIG. 5, a substrate 1010 may be provided. The substrate 1010 may include, for example, a semiconductor, a conductor, or an insulator. In an embodiment, the substrate 1010 may be a semiconductor substrate doped with a p-type or n-type dopant. The substrate 1010 may include a first surface 101051 and a second surface 101052 opposite to the first surface 101051. The substrate 1010 may include a doped well region formed in an active region that is an inner region adjacent to the first surface 101051. The doped well region may be doped with the same or different type of dopant as the substrate 1010.

Next, a device structure layer 1100 may be formed on the first surface 101051 of the substrate 1010. The device structure layer 1100 may include electronic devices electrically connected to the doped well region (not shown) of the substrate 1010. The electronic devices may include, for example, field effect transistors, capacitors, and the like. In an embodiment, the device structure layer 1100 may be formed through a front end of line (FEOL) process of a semiconductor device fabrication process.

Subsequently, a metal wiring layer 1200 may be formed on the device structure layer 1100. Although not shown, the metal wiring layer 1200 may electrically connect the electronic devices of the device structure layer 1100 to each other or may electrically connect the electronic devices to the substrate 1010. The metal wiring layer 1200 may include, for example, aluminum (Al), copper (Cu), tungsten (W), titanium (Ti), tantalum (Ta), or any combination thereof. In an embodiment, the metal wiring layer 1200 may be formed through a back end of line (BEOL) process of the semiconductor device fabrication process. The metal wiring layer 1200 may be formed using, for example, sputtering, chemical vapor deposition, atomic layer deposition, or the like.

Subsequently, a base buffer layer 1300 may be formed on the metal wiring layer 1200. The base buffer layer 1300 may include an insulating material having a porous structure. In an embodiment, the insulating material may include a metal-organic framework. The metal-organic framework may have a two-dimensional structure or a three-dimensional structure. The metal-organic framework may be substantially the same as the metal-organic framework M described above with reference to FIG. 2A. In an embodiment, the base buffer layer 1300 may include a metal-organic framework layer N in which the metal-organic frameworks M1, M2, M3, and M4 of the two-dimensional structure are sequentially stacked, as described above with reference to FIG. 2B.

In an embodiment, the base buffer layer 1300 may be formed by forming metal-organic frameworks in a form of a two-dimensional sheet including cavities by using atomic layer deposition. In this case, the metal-organic frameworks may be sequentially stacked on the metal wiring layer 1200. As an example, the atomic layer deposition may be performed using trimethylaluminum (AlMe₃) or dimethylaluminum iso-propoxide ([Al-Me₂ⁱOPr]₂) as a precursor.

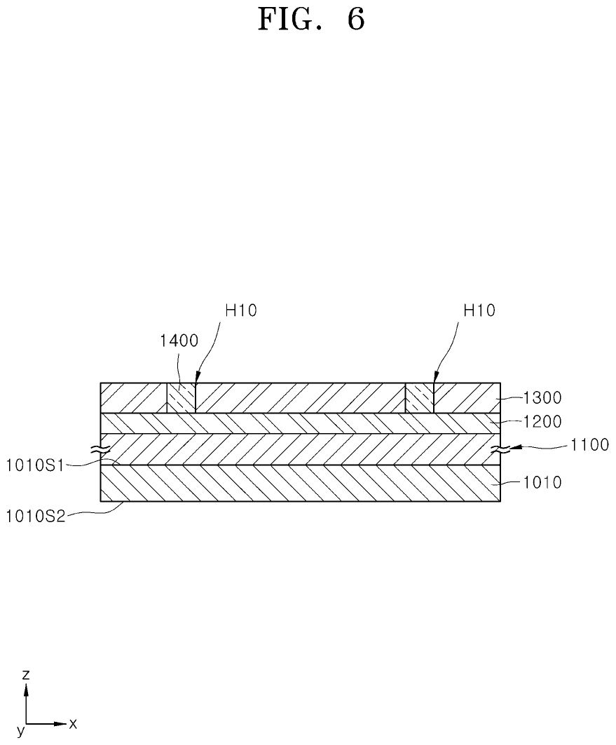

Referring to FIG. 6, the base buffer layer 1300 may be patterned on the metal wiring layer 1200 to form first via holes H10. The first via holes H10 may expose the metal wiring layer 1200. Next, the first via holes H10 may be filled with a conductive material to form vias 1400. The vias 1400 may include, for example, aluminum (Al), copper (Cu), tungsten (W), titanium (Ti), tantalum (Ta), or any combination thereof. In an embodiment, each of the vias 1400 may be formed of the same material as the metal wiring layer 1200. The vias 1400 may be formed using, for example, sputtering, chemical vapor deposition, atomic layer deposition, and the like.

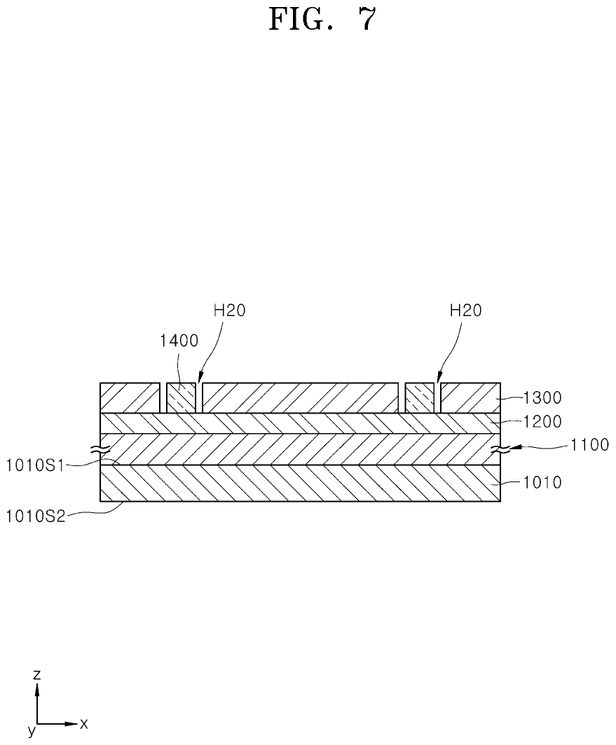

Referring to FIG. 7, the base buffer layer 1300 may be selectively etched on the metal wiring layer 1200 to form second via holes H20 exposing the metal wiring layer 1200. The second via holes H20 may be trench patterns surrounding the vias 1400. The second via holes H20 may expose side surfaces of the vias 1400 and the base buffer layer 1300.

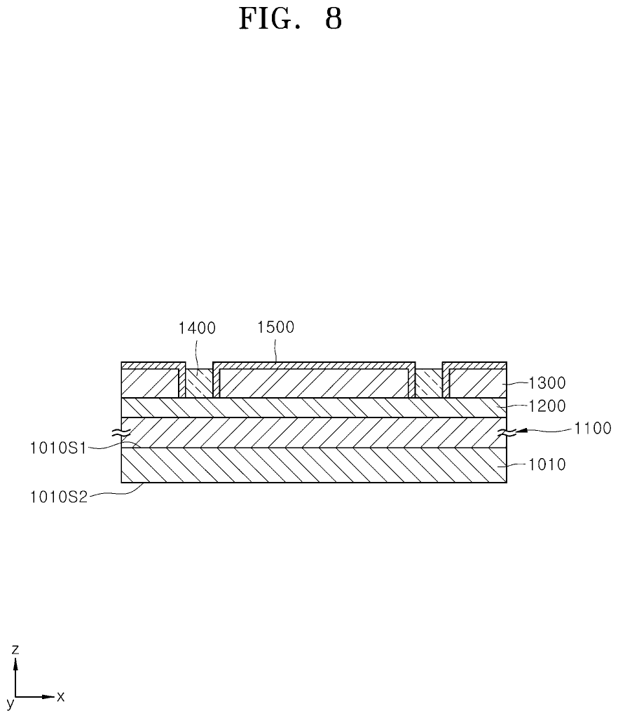

Referring to FIG. 8, a first barrier material layer 1500 may be formed to fill the second via holes H20 and to cover an upper surface of the base buffer layer 1300. The first barrier material layer 1500 may include a two-dimensional material.

In an embodiment, the first barrier material layer 1500 may include the two-dimensional material, MXene. MXene may include a two-dimensional material having a chemical formula of Mₙ₊₁Xₙ. In this case, n may be 1, 2, or 3, and M may include scandium (Sc), titanium (Ti), zirconium (Zr), hafnium (Hf), vanadium (V), niobium (Nb), tantalum (Ta), chromium (Cr), molybdenum (Mo), tungsten (W), or any combination thereof. X may include carbon (C), nitrogen (N), or any combination thereof. That is, MXene may include, for example, transition metal carbide, transition metal nitride, or transition metal carbonitride.

In an embodiment, the first barrier material layer 1500 may have a structure in which at least two layers of MXene, which is the two-dimensional material, are stacked. The layer of MXene may be formed by using chemical vapor deposition or atomic layer deposition. As an example, the layer of MXene may be formed by using a source material including transition metal and a reaction gas including hydrocarbon. As an example, using a molybdenum source and methane gas, two-dimensional molybdenum carbide may be formed.

In an embodiment, the first barrier material layer 1500 might not be disposed on upper surfaces of the vias 1400. That is, after forming the first barrier material layer 1500, the upper surface of each of the vias 1400 may be exposed. When MXene is deposited on the upper surface of each of the vias 1400 by the chemical vapor deposition or the atomic layer deposition, MXene deposited on the upper surface of each of the vias 1400 may be removed through a selective etching process.

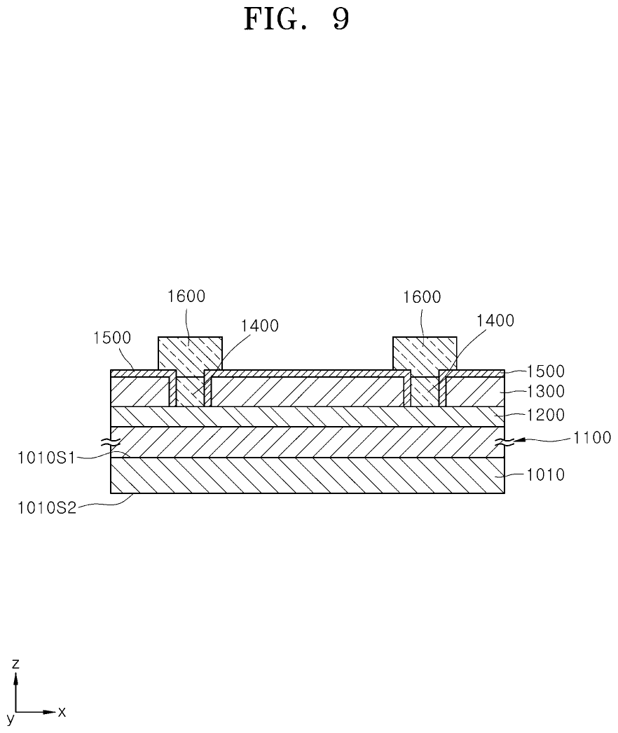

Referring to FIG. 9, connection pads 1600 may be formed over the base buffer layer 1300 and the first barrier material layer 1500 to be connected to the vias 1400. Each of the connection pads 1600 may include, for example, aluminum (Al), copper (Cu), tungsten (W), titanium (Ti), tantalum (Ta), or any combination thereof.

In an embodiment, a method of forming the connection pads 1600 may include a process of forming a pad material layer using, for example, sputtering or chemical vapor deposition and a process of patterning the formed pad material layer. In another embodiment, the method of forming the connection pads 1600 may proceed as a process of forming a metal plating pattern using an electrolytic plating method, an electroless plating method, or a combination thereof.

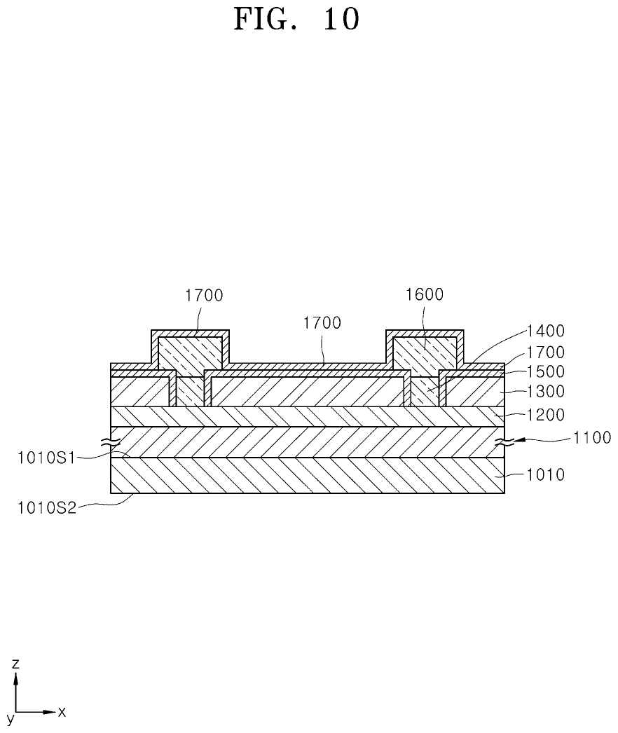

Referring to FIG. 10, a second barrier material layer 1700 may be formed on the first barrier material layer 1500 to cover the connection pads 1600. The material and method of forming the second barrier material layer 1700 may be substantially the same as the material and method of forming the first barrier material layer 1500.

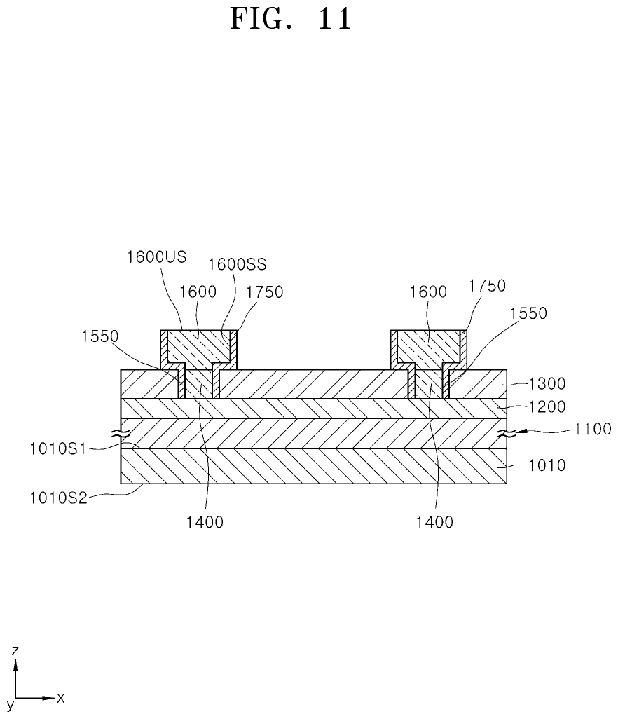

Referring to FIG. 11, the first and second barrier material layers 1500 and 1700 may be selectively etched on the base buffer layer 1300 to form a via barrier layer 1550 and a pad barrier layer 1750. In this case, an upper surface 1600US of each of the connection pads 1600 may be exposed. The via barrier layer 1550 may be disposed between the vias 1400 and the base buffer layer 1300, and the pad barrier layer 1750 may be disposed on side surfaces 1600SS of the connection pads 1600.

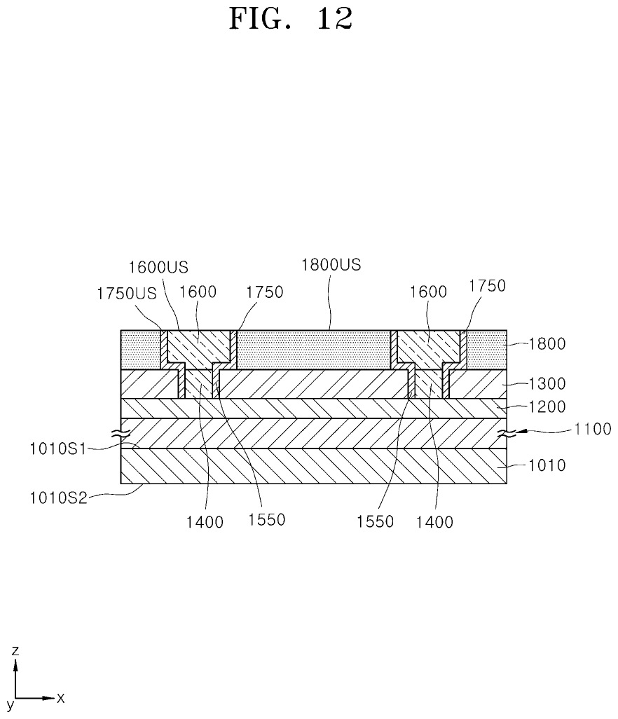

Referring to FIG. 12, a buffer material layer 1800 may be formed on the base buffer layer 1300 and may contact the pad barrier layer 1750. The buffer material layer 1800 may be disposed to surround the pad barrier layer 1750.

An upper surface 1800US of the buffer material layer 1800 may be located at the same level as the upper surface 1600US of the connection pad 1600 and an upper surface 1750US of the pad barrier layer 1750. The buffer material layer 1800 may include an insulating material having a porous structure. In an embodiment, the insulating material may include a metal-organic framework. The material of the buffer material layer 1800 may be substantially the same as that of the base buffer layer 1300.

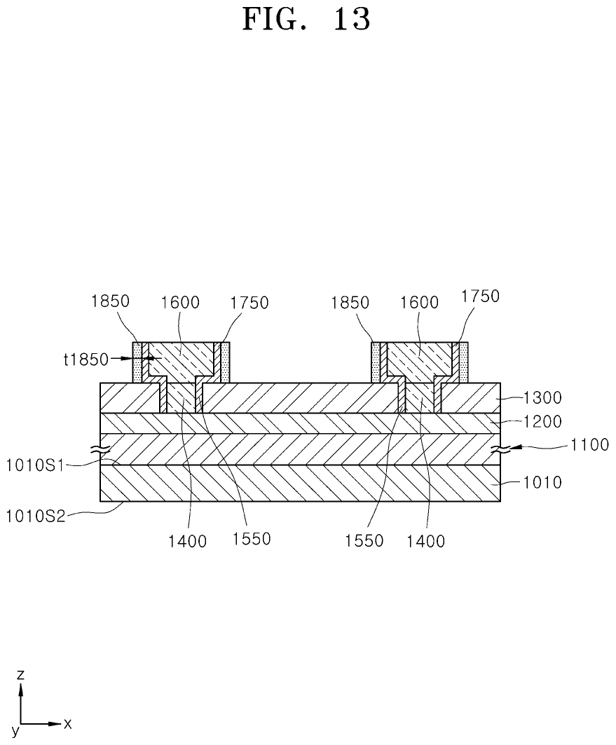

Referring to FIG. 13, the buffer material layer 1800 may be selectively etched on the base buffer layer 1300 to form a pad buffer layer 1850 that covers a sidewall of the pad barrier layer 1750. The pad buffer layer 1850 may be formed to have a predetermined thickness t1850 in a lateral direction (e.g., the x-direction).

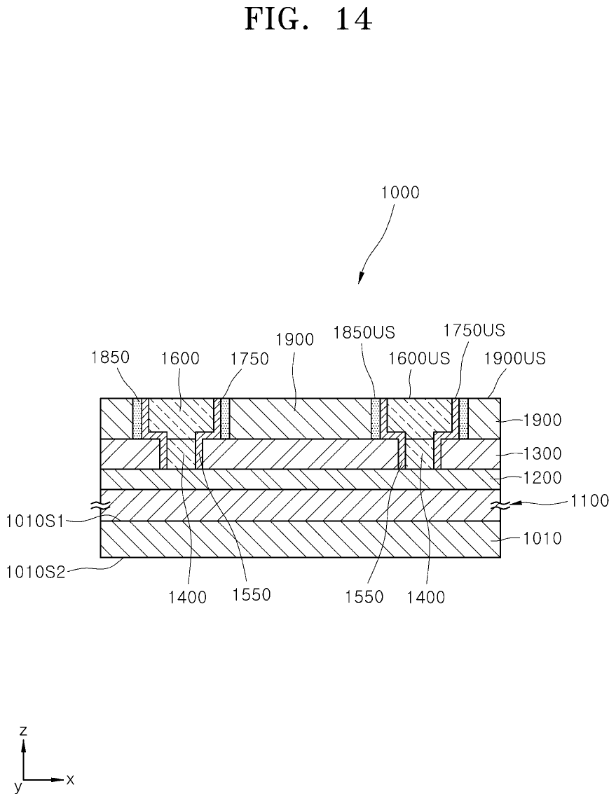

Referring to FIG. 14, a bonding dielectric layer 1900 may be formed on the base buffer layer 1300 to contact the pad buffer layer 1850. The bonding dielectric layer 1900 may be disposed to surround the pad buffer layer 1850. An upper surface 1900US of the bonding dielectric layer 1900 may be located at the same level as the upper surface 1600US of the connection pad 1600, the upper surface 1750US of the pad barrier layer 1750, and the upper surface 1850US of the pad buffer layer 1850. The bonding dielectric layer 1900 may include, for example, oxide, nitride, or oxynitride.

It is possible to form the first substrate structure 1000 according to an embodiment of the present disclosure by performing the above-described processes.

Meanwhile, the second substrate structure 2000 may also be formed by performing the processes described above with reference to FIGS. 5 to 14. In the description of the second substrate structure 2000 below, expressions of “on” and “over” are expressions of a relative concept based on a certain surface, and might not necessarily coincide with the upper side in the drawings.

Referring to FIG. 15, the second substrate structure 2000 may include a substrate 2010 having a first surface 2010S1 and a second surface 2010S2, a device structure layer 2100 disposed on the first surface 2010S1 of the substrate 2010, and a metal wiring layer 2200 disposed on the device structure layer 2100. In addition, the second substrate structure 2000 may include a base buffer layer 2300 disposed on the metal wiring layer 2200, vias 2400 disposed in the base buffer layer 2300, a via barrier layer 2550 disposed between each of the vias 2400 and the base buffer layer 2300. In addition, the second substrate structure 2000 may include connection pads 2600 disposed over the bae buffer layer 2300 to be connected to the vias 2400, and a pad barrier layer 2750, a pad buffer layer 2850, and a bonding dielectric layer 2900 that sequentially surround the connection pads 2600 over the base buffer layer 2300.

In an embodiment, a configuration of the second substrate structure 2000 may be substantially the same as a configuration of the first substrate structure 1000. That is, the substrate 2010, the device structure layer 2100, the metal wiring layer 2200, the base buffer layer 2300, the vias 2400, the via barrier layer 2550, the connection pads 2600, the pad barrier layer 2750, the pad buffer layer 2850, and the bonding dielectric layer 2900 of the second substrate structure 2000 may be substantially the same as the substrate 1010, the device structure layer 1100, the metal wiring layer 1200, the base buffer layer 1300, the vias 1400, the via barrier layer 1550, the connection pads 1600, the pad barrier layer 1750, the pad buffer layer 1850, and the bonding dielectric layer 1900 of the first substrate structure 1000.

Hereinafter, for convenience of explanation, the substrate 1010, the device structure layer 1100, the connection pads 1600, the pad barrier layer 1750, the pad buffer layer 1850, and the bonding dielectric layer 1900 of the first substrate structure 1000 will be referred to as a first substrate 1010, a first device structure layer 1100, first connection pads 1600, a first pad barrier layer 1750, a first pad buffer layer 1850, and a first bonding dielectric layer 1900, respectively. In addition, the substrate 2010, the device structure layer 2100, the connection pads 2600, the pad barrier layer 2750, the pad buffer layer 2850, and the bonding dielectric layer 2900 of the second substrate structure 2000 will be referred to as a second substrate 2010, a second device structure layer 2100, second connection pads 2600, a second pad barrier layer 2750, a second pad buffer layer 2850, and a second bonding dielectric layer 2900, respectively.

Referring to FIG. 15, the first substrate structure 1000 and the second substrate structure 2000 may be aligned with each other at a predetermined interval. In this case, the first connection pads 1600 of the first substrate structure 1000 and the second connection pads 2600 of the second substrate structure 2000 may be aligned with each other, and the first bonding dielectric layer 1900 of the first substrate structure 1000 and the second bonding dielectric layer 2900 of the second substrate structure 2000 may be aligned with each other.

Referring to FIG. 16, the first connection pads 1600 and the second connection pads 2600 may be bonded to each other, and the first bonding dielectric layer 1900 and the second bonding dielectric layer 2900 may be bonded to each other, thereby forming a connection portion C1000 of the first and second substrate structures 1000 and 2000.

In an embodiment, a process of forming the connection portion C1000 may include performing a pre-treatment process for bonding the first and second substrate structures 1000 and 2000 and performing an annealing thermal process after the first and second substrate structures 1000 and 2000 contact each other.

The pre-treatment process may include performing plasma treatment on the exposed surfaces of the first and second connection pads 1600 and 2600, the first and second bonding dielectric layers 1900 and 2900, the first and second pad barrier layers 1750 and 2750, and the first and second pad buffer layers 1850 and 2850 of the first and second substrate structures 1000, respectively. Through the pre-treatment process, the exposed surfaces of the first and second substrate structures 1000 and 2000 are conditioned for the bonding reaction to be performed.

After the pre-treatment process is completed, the first and second connection pads 1600 and 2600, the first and second bonding dielectric layers 1900 and 2900, the first and second pad buffer layers 1850 and 2850, and the first and second pad barrier layers 1750 and 2750 of the first and second substrate structures 1000 and 2000 may contact each other, and an annealing thermal process may be performed. The annealing thermal process may be performed at a temperature above room temperature and at a temperature of, for example, 400° C. or less. Through the annealing thermal process, the first and second substrate structures 1000 and 2000 may be bonded to each other. In an embodiment, the first and second connection pads 1600 and 2600 may form a metal bond at a bonding surface BP10. The first and second bonding dielectric layers 1900 and 2900 may form a covalent bond at the bonding surface BP10.

By performing the above-described processes, the semiconductor device according to an embodiment of the present disclosure may be fabricated. Referring to FIG. 16, in the connection portion C1000, a surface area 1600A of the first connection pad 1600 and a surface area 2600A of the second connection pad 2600 may be substantially the same as each other. Accordingly, the first and second connection pads 1600 and 2600 may be disposed to align with each other. In an embodiment, the first and second connection pads 1600 and 2600 may overlap with each other. In another embodiment not shown in FIG. 16, in the connection portion C1000, the surface area 1600A of the first connection pad 1600 and the surface area 2600A of the second connection pad 2600 may be different from each other. As an example, as in the semiconductor device 2 described with reference to FIG. 3, the surface area 2600A of the second connection pad 2600 in the connection portion C1000 may be smaller than the surface area 1600A of the first connection pad 1600.

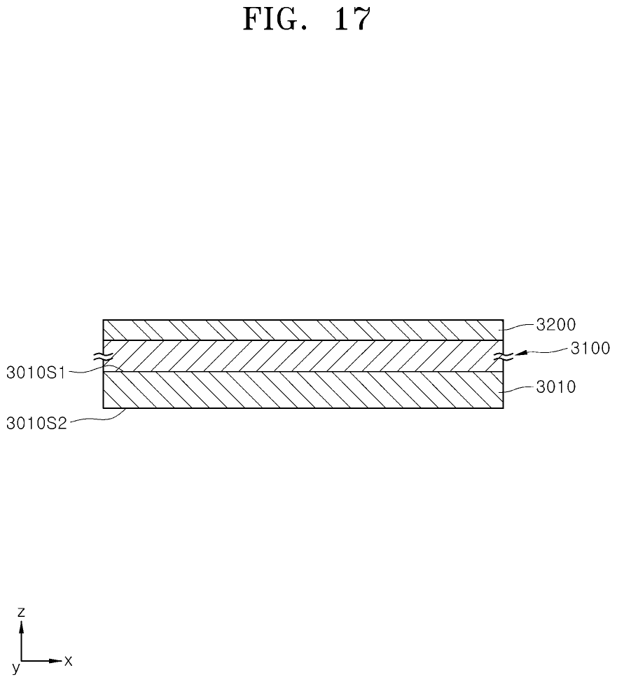

FIGS. 17 to 28 are cross-sectional views schematically illustrating a method of fabricating a semiconductor device according to another embodiment of the present disclosure. The method of fabricating the semiconductor device in connection with FIGS. 17 to 28 may be applied to the method of fabricating the semiconductor device 3 of FIG. 4. The method of fabricating the semiconductor device may include fabricating a first substrate structure 1000, fabricating a second substrate structure 3000, and bonding the first and second substrate structures 1000 and 3000 to each other.

In an embodiment, the first substrate structure 1000 may be fabricated through the method described above with reference to FIGS. 5 to 14. The second substrate structure 3000 may be fabricated by performing processes related to FIGS. 17 to 26 below. In the description of the second substrate structure 3000 below, expressions of “on” and “over” are expressions of a relative concept based on a certain surface, and might not necessarily coincide with the upper side in the drawings.

Referring to FIG. 17, a substrate 3010 including a first surface 3010S1 and a second surface 3010S2 may be provided. The substrate 3010 may be substantially the same as the substrate 1010 described above with reference to FIG. 5. The substrate 3010 may include a doped well region formed in an active region, which is an inner region adjacent to the first surface 3010S1.

Next, a device structure layer 3100 may be formed on the first surface 3010S1 of the substrate 3010. The material and forming method of the device structure layer 3100 may be substantially the same as the material and forming method of the device structure layer 1100 described above with reference to FIG. 5. Next, a metal wiring layer 3200 may be formed on the device structure layer 3100. The material and forming method of the metal wiring layer 3200 may be substantially the same as the material and forming method of the metal wiring layer 1200 described above with reference to FIG. 5.

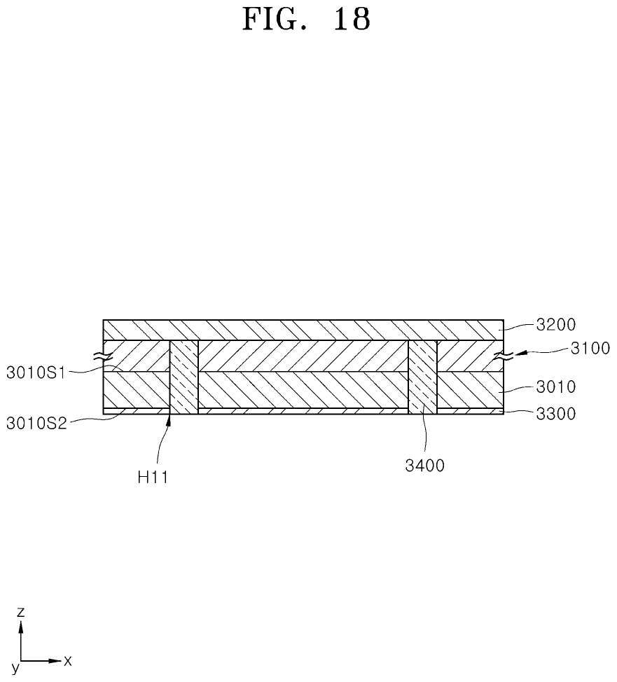

Referring to FIG. 18, a base buffer layer 3300 may be formed on the second surface 3010S2 of the substrate 3010. The material and forming method of the base buffer layer 3300 may be substantially the same as the material and forming method of the base buffer layer 1300 described above with reference to FIG. 5.

Next, the base buffer layer 3300, the substrate 3010, and the device structure layer 3100 may be sequentially patterned to form through via holes H11 exposing the metal wiring layer 3200. Subsequently, the through via holes H11 may be filled with a conductive material to form through vias 3400. The through vias 3400 may include, for example, copper (Cu). The through vias 3400 may be formed, for example, using a plating method.

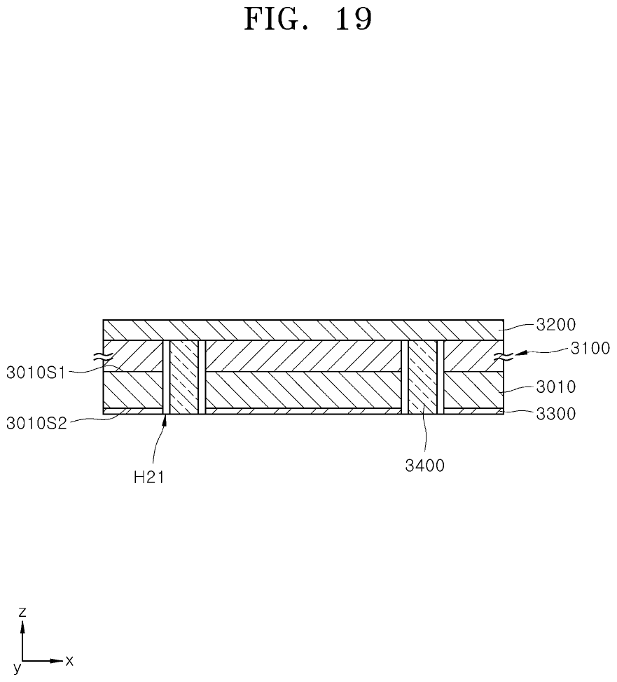

Referring to FIG. 19, the base buffer layer 3300, the substrate 3010, and the device structure layer 3100 may be sequentially patterned to form second through via holes H21 around the through vias 3400. The second through via holes H21 may expose the metal wiring layer 3200. In addition, the second via holes H21 may expose side surfaces of the through vias 3400, the substrate 3010, and the device structure layer 3100.

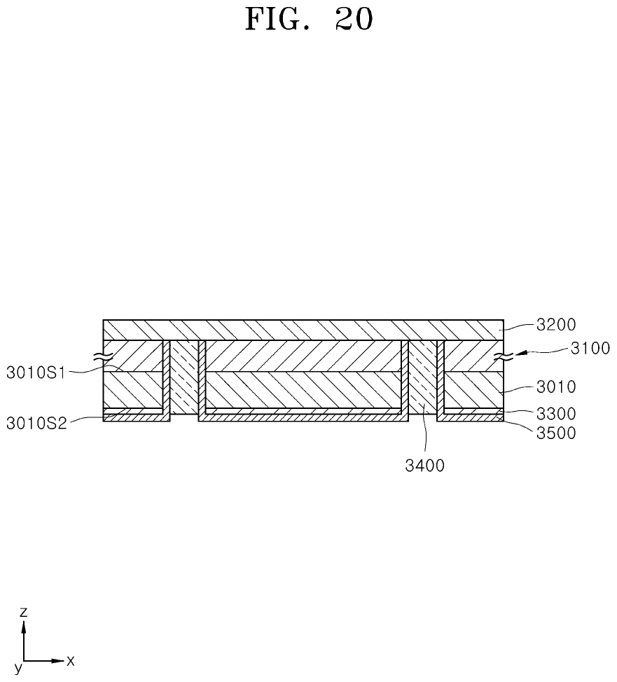

Referring to FIG. 20, a first barrier material layer 3500 may be formed to fill the second via holes H21 and to cover a surface of the base buffer layer 3300 over the metal wiring layer 3200. The first barrier material layer 3500 might not be disposed on surfaces of the through vias 3400. That is, after forming the first barrier material layer 3500, the surfaces of the through vias 3400 may be exposed. The material and forming method of the first barrier material layer 3500 may be substantially the same as the material and forming method of the first barrier material layer 1500 described above with reference to FIG. 8.

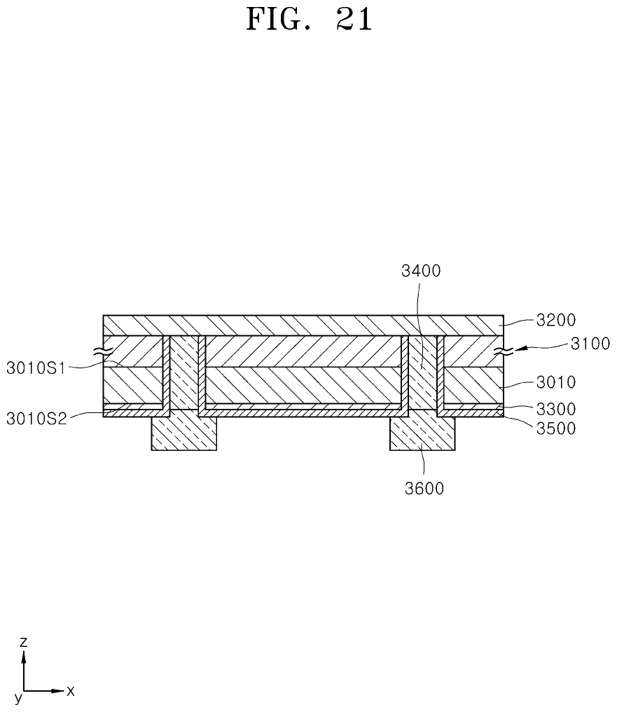

Referring to FIG. 21, connection pads 3600 may be formed to be connected to the through vias 3400 on the first barrier material layer 3500. The material and forming method of the connection pads 3600 may be substantially the same as the material and forming method of the connection pads 1600 described above with reference to FIG. 9.

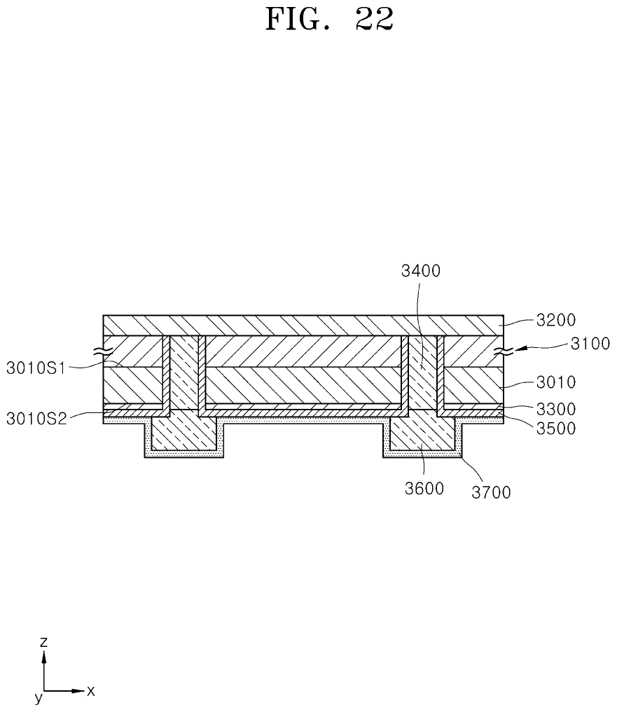

Referring to FIG. 22, a second barrier material layer 3700 may be formed to cover the connection pads 3600 on the first barrier material layer 3500. The material and forming method of the second barrier material layer 3700 may be substantially the same as the material and forming method of the first barrier material layer 3500.

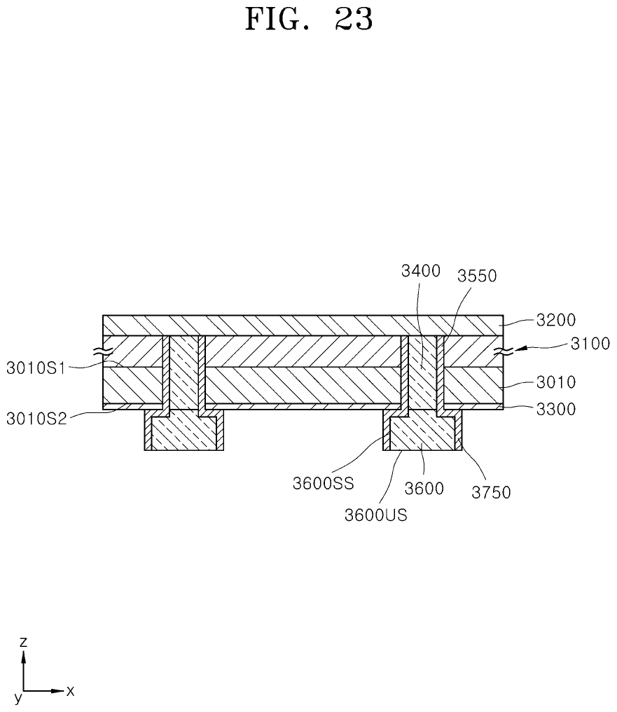

Referring to FIG. 23, the first and second barrier material layers 3500 and 3700 may be selectively etched on the base buffer layer 3300 to form a via barrier layer 3550 and a pad barrier layer 3750. In this case, upper surfaces 3600US of the connection pads 3600 may be exposed. The via barrier layer 3550 may be formed between the through vias 3400 and the device structure layer 3100, between the through vias 3400 and the substrate 3010, and between the through vias 3400 and the base buffer layer 3300. The pad barrier layer 3750 may be formed on a side surface 3600SS of each of the connection pads 3600.

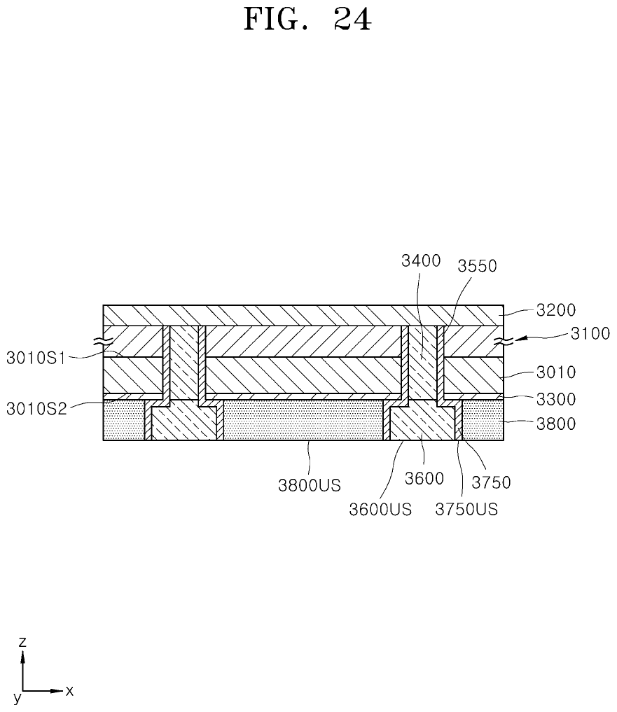

Referring to FIG. 24, a buffer material layer 3800 may be formed to contact the pad barrier layer 3750 on the base buffer layer 3300. The buffer material layer 3800 may be disposed to surround the pad barrier layer 3750. An upper surface 3800US of the buffer material layer 3800 may be located at the same level as the upper surface 3600US of the connection pad 3600 and an upper surface 3750US of the pad barrier layer 3750. The material and forming method of the buffer material 3800 may be substantially the same as the material and forming method of the buffer material layer 1800 of FIG. 12.

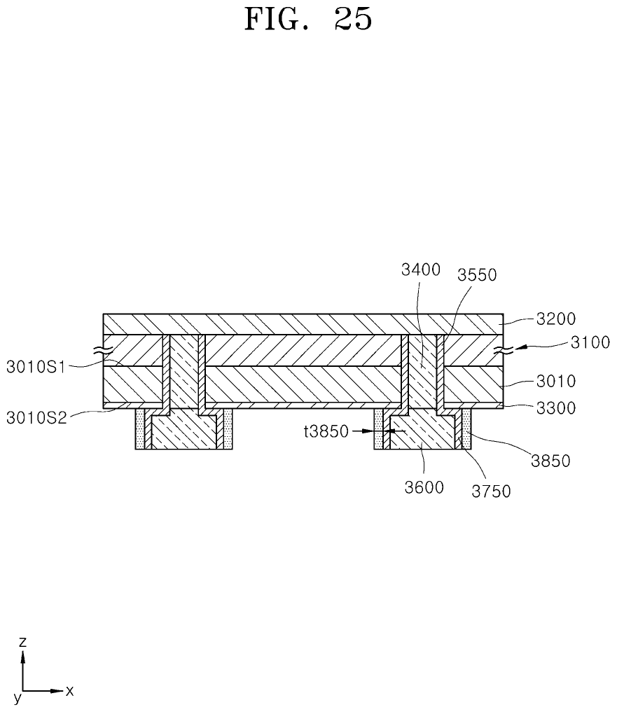

Referring to FIG. 25, the buffer material layer 3800 may be selectively etched on the base buffer layer 3300 to form a pad buffer layer 3850 covering the pad barrier layer 3750. The pad buffer layer 3850 may be formed to have a predetermined thickness t3850 in a lateral direction (e.g., the x-direction).

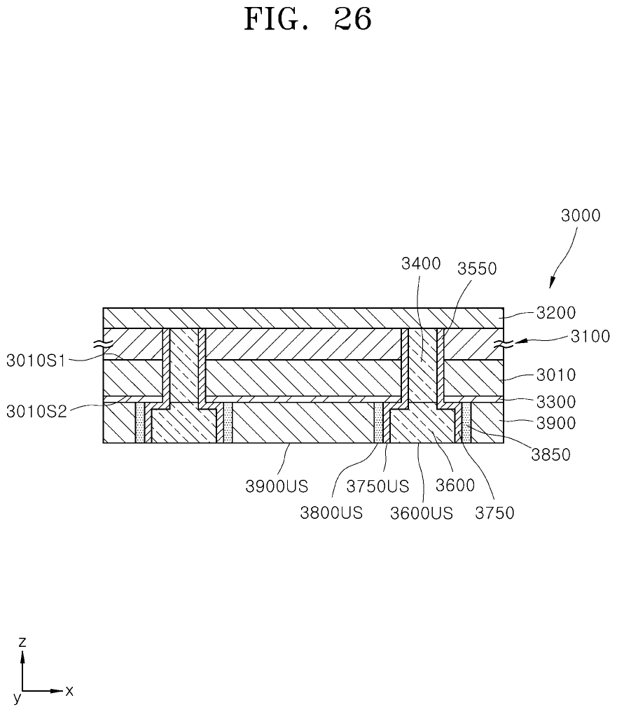

Referring to FIG. 26, a bonding dielectric layer 3900 may be formed to contact the pad buffer layer 3850 on the base buffer layer 3300. The bonding dielectric layer 3900 may be disposed to surround the pad buffer layer 3850. An upper surface 3900US of the bonding dielectric layer 3900 may be located at the same level as the upper surface 3600US of the connection pad 3600, the upper surface 3750US of the pad barrier layer 3750, and the upper surface 3850US of the pad buffer layer 3850. The material and forming method of the bonding dielectric layer 3900 may be substantially the same as the material and forming method of the bonding dielectric layer 1900 of FIG. 14.

By performing the above-described processes, the second substrate structure 3000 according to an embodiment of the present disclosure may be formed.

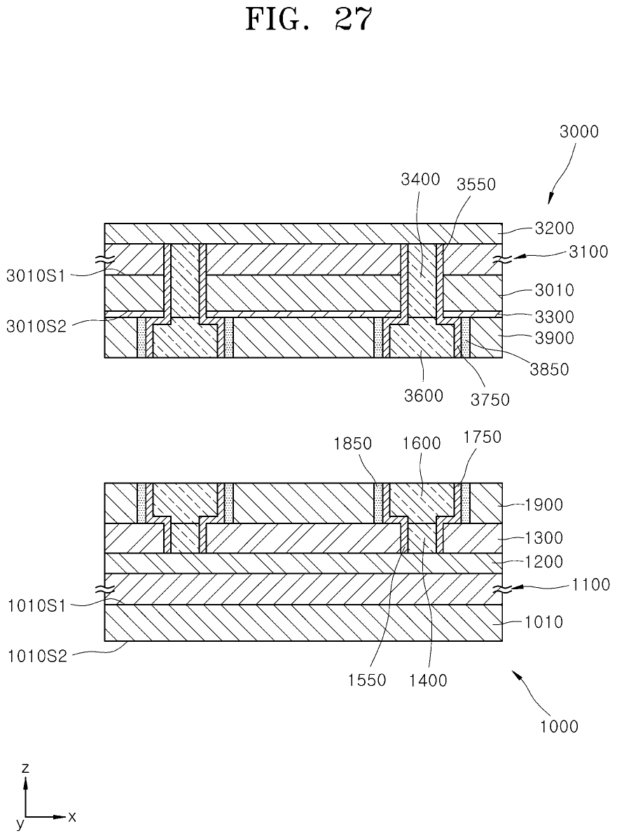

Referring to FIG. 27, the first substrate structure 1000 and the second substrate structure 3000 may be aligned with a predetermined distance therebetween. Hereinafter, for convenience of description, the substrate 1010, the device structure layer 1100, the connection pads 1600, the pad barrier layer 1750, the pad buffer layer 1850, and the bonding dielectric layer 1900 of the first substrate structure 1000 may be referred to as a first substrate 1010, a first device structure layer 1100, first connection pads 1600, a first pad barrier layer 1750, a first pad buffer layer 1850, and a first bonding dielectric layer 1900, respectively. In addition, the substrate 3010, the device structure layer 3100, the connection pads 3600, the pad barrier layer 3750, the pad buffer layer 3850, and the bonding dielectric layer 3900 of the second substrate structure 3000 may be referred to as a second substrate 3010, a second device structure layer 3100, second connection pads 3600, a second pad barrier layer 3750, a second pad buffer layer 3850, and a second bonding dielectric layer 3900, respectively.

Referring to FIG. 27, the first connection pads 1600 of the first substrate structure 1000 and the second connection pads 3600 of the second substrate structure 3000 may be aligned with each other, and the first bonding dielectric layer 1900 of the first substrate structure 1000 and the second bonding dielectric layer 3900 of the second substrate structure 3000 may be aligned with each other.

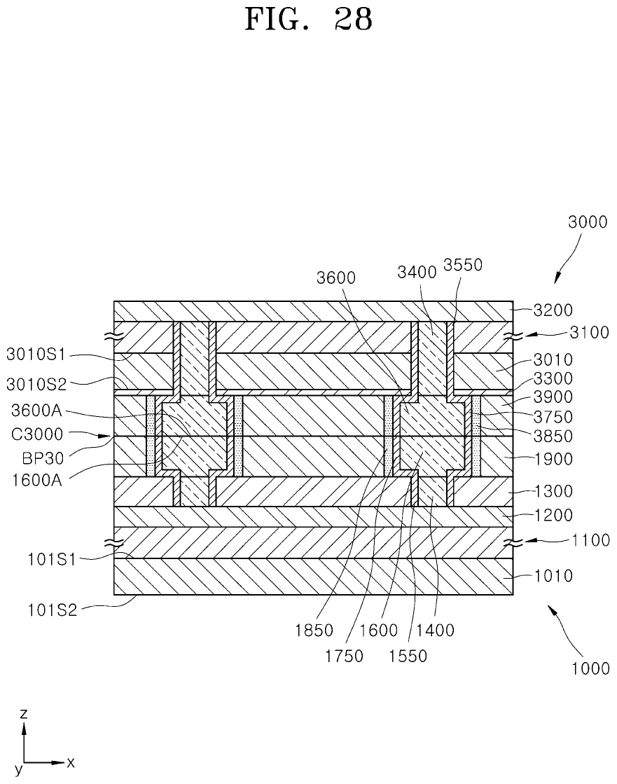

Referring to FIG. 28, the first connection pads 1600 and the second connection pads 3600 may be bonded to each other, and the first bonding dielectric layer 1900 and the second bonding dielectric layer 3900 may be bonded to each other, thereby forming a connection portion C3000 of the first and second substrate structures 1000 and 3000. The connection portion C3000 may include a bonding surface BP30 of the first and second substrate structures 1000 and 3000.

In an embodiment, a process of forming the connection portion C3000 may include a process of performing a pre-treatment process for bonding the first and second substrate structures 1000 and 3000, and a process of performing an annealing thermal process after contacting the first and second substrate structures 1000 and 3000. The process of forming the connection portion C3000 may be substantially the same as the process of forming the connection portion C1000 described above with reference to FIG. 16.

In an embodiment, the first and second connection pads 1600 and 3600 may form a metal bond at the bonding surface BP30. The first and second bonding dielectric layers 1900 and 3900 may form a covalent bond at the bonding surface BP30.

By performing the above-described processes, the semiconductor device according to an embodiment of the present disclosure may be fabricated. Referring to FIG. 28, in the connection portion C3000, a surface area 1600A of the first connection pad 1600 and a surface area 3600A of the second connection pad 3600 may be substantially the same. Accordingly, the first and second connection pads 1600 and 3600 may be disposed to align with each other. In an embodiment, the first and second connection pads 1600 and 3600 may be disposed to overlap with each other. In another embodiment not shown in FIG. 28, in the connection portion C3000, the surface area 1600A of the first connection pad 1600 and the surface area 3600A of the second connection pad 3600 may be different from each other. As an example, as in the semiconductor device 2 described with reference to FIG. 3, in the connection portion C3000, the surface area 3600A of the second connection pad 3600 may be smaller than the surface area 1600A of the first connection pad 1600.

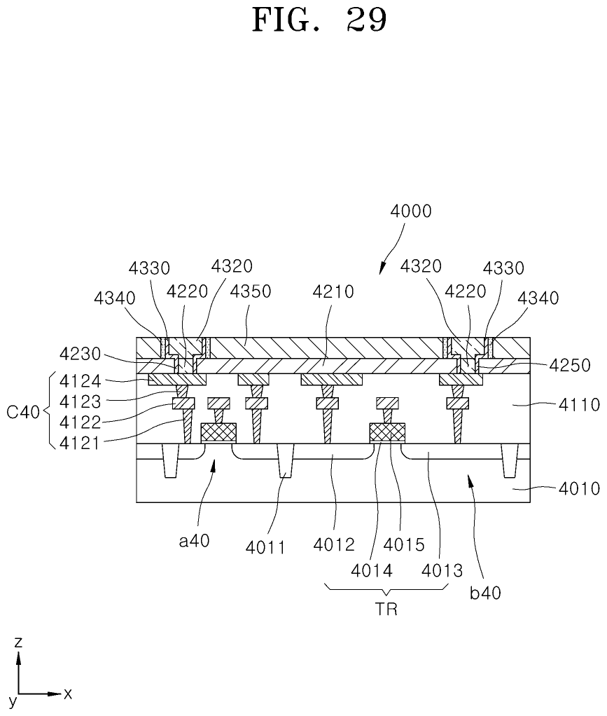

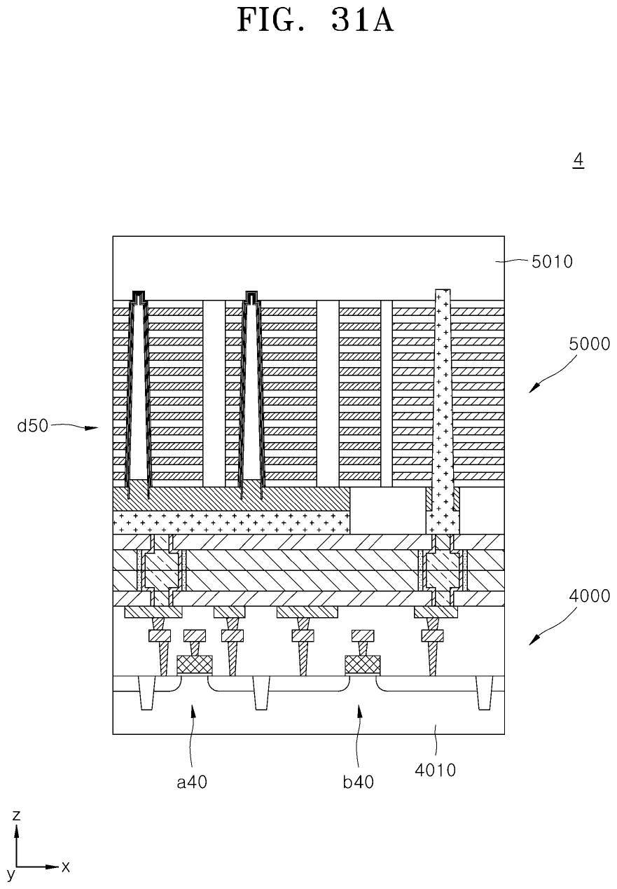

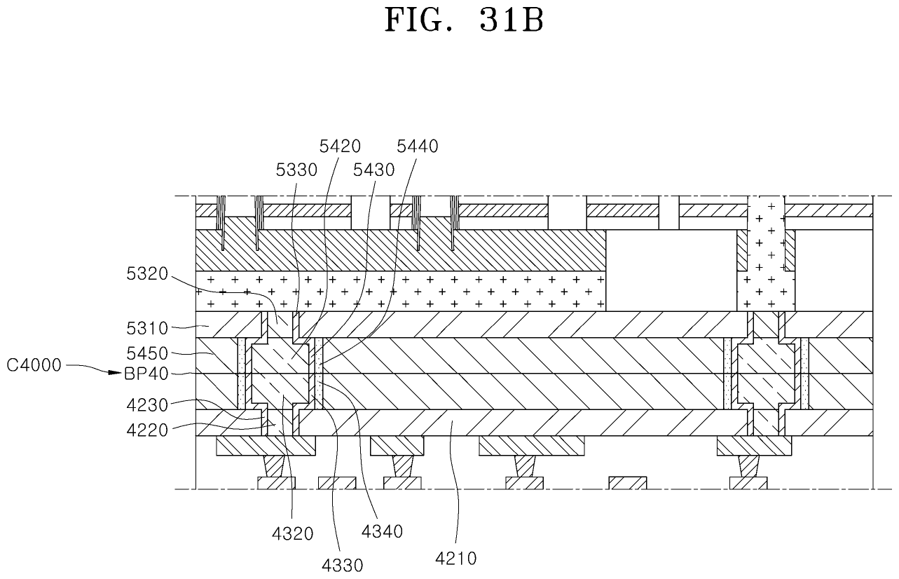

FIGS. 29, 30, 31A, and 31B are cross-sectional views schematically illustrating a method of fabricating a semiconductor device according to another embodiment of the present disclosure, and a semiconductor device fabricated by the method. FIG. 31B is an enlarged view of a connection portion of the semiconductor device shown in FIG. 31A. In an embodiment, the semiconductor device 4 may include a memory device. As an example, the memory device may be a NAND-type flash memory device having a three-dimensional structure.

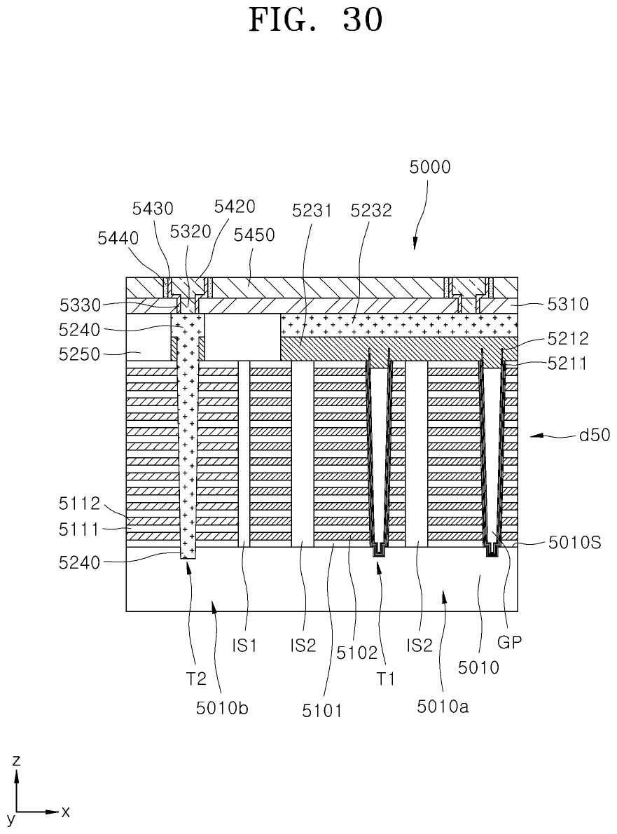

In an embodiment, the method of fabricating the semiconductor device 4 may include a process of forming a first substrate structure 4000 including a memory cell driver circuit, which will be described in relation to FIG. 29, a process of forming a second substrate structure 5000 including a memory cell structure, which will be described in relation to FIG. 30, and a process of bonding the first substrate structure 4000 and the second substrate structure 5000, which will be described in relation to FIGS. 31A and 31B.

Referring to FIG. 29, the first substrate structure 4000 may be fabricated on a substrate 4010 through a semiconductor integration process. The first substrate structure 4000 may include the substrate 4010, memory cell driver circuits a40 and b40 disposed over the substrate 4010, driver circuit wirings C40 electrically connected to the memory cell driver circuits a40 and b40 over the substrate 4010, connection pads 4320 electrically connected to the driver circuit wirings C40 through vias 4220, and a pad buffer layer 4340 disposed in a lateral direction (e.g., the x-direction or the y-direction) of the connection pad 4320. In addition, the first substrate structure 4000 may include a pad barrier layer 4330 disposed between the connection pads 4320 and the pad buffer layer 4340. In addition, the first substrate structure 4000 may include a bonding dielectric layer 4350 disposed to contact the pad buffer layer 4340.

In an embodiment, the first substrate structure 4000 may include a base buffer layer 4210 disposed between an uppermost wiring layer 4124 of the driver circuit wirings C40 in a vertical direction (e.g., the z-direction) and the connection pads 4320, vias 4220 disposed in the base buffer layer 4210 and connecting the uppermost wiring layer 4124 to the connection pads 4320, and a via barrier layer 4230 disposed between the vias 4220 and the base buffer layer 4210 in a lateral direction (e.g., the x-direction).

The substrate 4010 may be a wafer to which a semiconductor integrated circuit process is applicable. For example, the substrate 4010 may be a silicon (Si) wafer doped with an n-type or p-type dopant. Although not shown, the substrate 4010 may include an n-type or p-type doped well region. Device isolation layers 4011 defining active regions may be formed in the substrate 4010. The device isolation layer 4011 may include an oxide layer, a nitride layer, or a combination thereof.

In an embodiment, the memory cell driver circuits a40 and b40 may include a source line driver circuit a40 connected to a source line of a memory cell and a page buffer circuit b40 as a peripheral circuit of the memory cell. Each of the source line driver circuit a40 and the page buffer circuit b40 may include a field effect transistor TR including first and second well regions 4012 and 4013, a gate dielectric layer 4014, and a gate electrode layer 4015. One of the first and second well regions 4012 and 4013 may function as a source region of the field effect transistor TR, and the other may function as a drain region of the field effect transistor TR.

Referring to FIG. 29, an interlayer insulating structure 4110 may be disposed over the substrate 4010 to cover the memory cell driver circuits a40 and b40. The interlayer insulating structure 4110 may include at least one insulating layer. The driver circuit wirings C40 may be disposed in the interlayer insulating structure 4110. The driver circuit wiring C40 may include first and second circuit pattern layers 4122 and 4124 disposed on different planes. In addition, the driver circuit wiring C40 may include a first contact plug 4121 electrically connecting the first circuit pattern layer 4122 to the first and second well regions 4012 and 4013 and a second contact plug 4123 electrically connecting the first and second circuit pattern layers 4122 and 4124 to each other.

The base buffer layer 4210, the vias 4220, and the via barrier layer 4230 may be disposed on the interlayer insulating structure 4110. The configurations and forming methods of the base buffer layer 4210, the vias 4220, and the via barrier layer 4230 may be substantially the same as the configurations and forming methods of the base buffer layer 1300, the vias 1400, and the via barrier layer 1550 of the first substrate structure 1000 described above with reference to FIGS. 5 to 14.

The connection pads 4320 may be disposed on the base buffer layer 4210 to be electrically connected to the vias 4220. In addition, the pad barrier layer 4330, the pad buffer layer 4340, and the bonding dielectric layer 4350 may be disposed adjacent to the connection pads 4320 in a lateral direction (e.g., the x-direction or the y-direction). The configurations and forming methods of the connection pads 4320, the pad barrier layer 4330, the pad buffer layer 4340, and the bonding dielectric layer 4350 may be substantially the same as the configurations and forming methods of the connection pads 1600, the pad barrier layer 1600, the pad barrier layer 1750, the pad buffer layer 1850, and the bonding dielectric layer 1900 of the first substrate 1000 described above with reference to FIGS. 5 to 14.

Referring to FIG. 30, the second substrate structure 5000 may be fabricated on substrate 5010 through a semiconductor integration process. The second substrate structure 5000 may include the substrate 5010, a memory cell structure d50 disposed over the substrate 5010, cell wirings 5231, 5232, and 5240 electrically connected to the memory cell structure d50 over the substrate 5010, connection pads 5420 electrically connected to the cell wirings 5231, 5232, and 5240 through vias 5320, and a pad buffer layer 5440 disposed in a lateral direction (e.g., the x-direction or the y-direction) of the connection pads 5420. In addition, the second substrate structure 5000 may include a pad barrier layer 5430 disposed between the connection pads 5420 and the pad buffer layer 5440. In addition, the second substrate structure 5000 may include a bonding dielectric layer 5450 disposed adjacent to the pad buffer layer 5440.

The substrate 5010 may be a wafer to which a semiconductor integrated circuit process is applicable. For example, the substrate 5010 may be a silicon (Si) wafer doped with an n-type or p-type dopant. Although not shown, the substrate 5010 may include an n-type or p-type doped well region.

The memory cell structure d50 may include cell gate structures 5010a and a contact plug structure 5010b that are disposed to be spaced apart from each other in a direction parallel to a surface 5010S of the substrate 5010. A first vertical insulating structure IS1 may be disposed between the cell gate structure 5010a and the contact plug structure 5010b. A second vertical insulating structure IS2 may be disposed between adjacent cell gate structures 5010a. The second vertical insulating structure IS2 may separate the neighboring cell gate structures 5010a from each other.

Each of the cell gate structures 5010a may include interlayer insulating layers 5101 and gate electrode layers 5102 that are alternately stacked in the z-direction perpendicular to the surface 5010S of the substrate 5010. Meanwhile, the memory cell structure d50 may include memory functional layers 5211 and channel layers 5212 disposed on sidewalls of trenches T1 penetrating through the cell gate structures 5010a to expose the substrate 5010.

Although not shown, each of the memory functional layers 5211 may include a barrier insulating layer, a charge storage layer, and a charge tunnel layer that are sequentially formed from the sidewall of the trench T1. The channel layer 5212 may be disposed on the memory functional layer 5211 and may be formed to protrude over the cell gate structure 5010a. The trench T1 in which the memory functional layer 5211 and the channel layer 5212 are formed may be filled with an insulating gap-fill material GP.

Common source line structures 5231 and 5232 may be disposed on the cell gate structure 5010a as the cell wirings. In an embodiment, the common source line structures 5231 and 5232 may include a first conductive layer 5231 that is a doped semiconductor layer and a second conductive layer 5232 that is a metal layer. As the first conductive layer 5231 contacts the channel layer 5212, the common source line structures 5231 and 5232 may be electrically connected to the channel layer 5212.

The contact plug structure 5010b may include interlayer insulating layers 5111 and sacrificial insulating layers 5112 that are alternately stacked in the z-direction perpendicular to the surface 5010S of the substrate 5010. Each of the interlayer insulating layers 5111 may be disposed at the same level as each of the interlayer insulating layers 5101 of the cell gate structure 5010a. Each of the sacrificial insulating layers 5112 may be disposed on the same level as each of the gate electrode layers 5102 of the cell gate structure 5010a.

Meanwhile, the memory cell structure d50 may include a vertical contact plug 5240 as the wiring layer, which fills a trench T2 penetrating the contact plug structure 5010b and exposing the substrate 5010. The vertical contact plug 5240 may protrude over the contact plug structure 5010b. The memory cell structure d50 may include a passivation layer 5250 to electrically insulate the vertical contact plug 5240 from the common source line structures 5231 and 5232.

In an embodiment, the second substrate structure 5000 may include a base buffer layer 5310 disposed between the uppermost layer 5232 of the common source line structures 5231, 5232 and the vertical contact plug 5240 and the connection pad 5420 in a vertical direction (e.g., the z-direction). The vias 5320 may be disposed in the base buffer layer 5310 and connect the uppermost layer 5232 and the vertical contact plug 5240 to the connection pads 5420. In addition, the second substrate structure 500 may include a via barrier layer 5330 disposed between the vias 5320 and the base buffer layer 5310 in a lateral direction (e.g., the x-direction).

The configurations and forming methods of the base buffer layer 5310, the vias 5320, and the via barrier layer 5330 may be substantially the same as the configurations and forming methods of the base buffer layer 1300, the vias 1400, and the via barrier layer 1550 of the first substrate structure 1000 described above with reference to FIGS. 5 to 14, respectively.

Referring to FIG. 30 again, the connection pads 5420 electrically connected to the vias 5320 may be disposed on the base buffer layer 5310. In addition, the pad barrier layer 5430, the pad buffer layer 5440, and the bonding dielectric layer 5450 may be disposed adjacent to the connection pads 5420 in a lateral direction (e.g., the x-direction or the y-direction). The configurations and forming methods of the connection pads 5420, the pad barrier layer 5430, the pad buffer layer 5440, and the bonding dielectric layer 5450 may be substantially the same as the configurations and forming methods of the connection pads 1600, the pad barrier layer 1750, the pad buffer layer 1850, and the bonding dielectric layer 1900 of the first substrate structure 1000 described above with reference to FIGS. 5 to 14, respectively.

Referring to FIGS. 31A and 31B, together with FIGS. 29 and 30, the connection pads 4320 of the first substrate structure 4000 and the connection pads 5420 of the second substrate structure 5000 may be bonded to each other, and the bonding dielectric layer 4350 of the first substrate structure 4000 and the bonding dielectric layer 5450 of the second substrate structure 5000 may be bonded to each other, thereby fabricating a semiconductor device 4 including a connection portion C4000. The connection portion C4000 may include a bonding surface BP40 of the first and second substrate structures 4000 and 5000.

In an embodiment, a process of forming the connection portion C4000 may include a process of performing a pre-treatment for bonding the first and second substrate structures 4000 and 5000, and a process of performing an annealing thermal process after bonding the first and second substrate structures 4000 and 5000 to each other. The process of forming the connection portion C4000 may be substantially the same as the process of forming the connection portion C1000 described above with reference to FIG. 16.

In an embodiment, the first and second connection pads 4320 and 5420 may form a metal bond at the bonding surface BP40. The first and second bonding dielectric layers 4350 and 5450 may form a covalent bond at the bonding surface BP40. By performing the above-described processes, the semiconductor device according to an embodiment of the present disclosure may be fabricated.

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor device comprising:
a first stacked structure that includes a first base body, a first connection pad disposed over a surface of the first base body, and a first pad buffer layer disposed adjacent to the first connection pad, the first pad buffer layer including a first insulating material having a porous structure;
a second stacked structure that includes a second base body, a second connection pad disposed over a surface of the second base body, and a second pad buffer layer disposed adjacent to the second connection pad, the second pad buffer layer including a second insulating material having a porous structure; and
a connection portion of the first and second stacked structures that connects the first and second connection pads with each other.

2. The semiconductor device of claim 1, wherein the first and second insulating materials having the porous structure comprise a metal-organic framework.

3. The semiconductor device of claim 2, wherein the metal-organic framework has a two-dimensional structure including cavities, and
wherein each of the first and second pad buffer layers comprises at least one layer of the metal-organic framework.

4. The semiconductor device of claim 1, further comprising:
a first pad barrier layer disposed between the first connection pad and the first pad buffer layer, the first pad barrier layer including a two-dimensional material; and
a second pad barrier layer disposed between the second connection pad and the second pad buffer layer, the second pad barrier layer including a two-dimensional material.

5. The semiconductor device of claim 4, wherein the two-dimensional material of each of the first and second pad barrier layers comprises MXene.

6. The semiconductor device of claim 5,
wherein MXene of each of the first and second pad barrier layers has a formula of Mₙ₊₁Xₙ, and
wherein n is 1, 2, or 3, M includes at least one selected from scandium (Sc), titanium (Ti), zirconium (Zr), hafnium (Hf), vanadium (V), niobium (Nb), tantalum (Ta), chromium (Cr), molybdenum (Mo), and tungsten (W), and X includes at least one selected from carbon (C) and nitrogen (N).

7. The semiconductor device of claim 5, wherein each of the first and second pad barrier layers comprises at least one layer of MXene.

8. The semiconductor device of claim 1, wherein in the connection portion, a surface area of the first connection pad is substantially the same as a surface area of the second connection pad.

9. The semiconductor device of claim 1, wherein in the connection portion, a surface area of the first connection pad is different from a surface area of the second connection pad.

10. The semiconductor device of claim 1,
wherein the first stacked structure further includes a first bonding dielectric layer disposed adjacent to the first connection pad in a lateral direction,
wherein the second stacked structure further includes a second bonding dielectric layer disposed adjacent to the second connection pad in a lateral direction, and
wherein the connection portion further includes bonding of the first bonding dielectric layer and the second bonding dielectric layer.

11. The semiconductor device of claim 1, wherein the connection portion further includes bonding of the first and second pad buffer layers.

12. The semiconductor device of claim 1,
wherein the first pad buffer layer is disposed to surround the first connection pad over the surface of the first base body, and
wherein the second pad buffer layer is disposed to surround the second connection pad over the surface of the second base body.

13. The semiconductor device of claim 1, wherein the first stacked structure further includes:
a metal wiring layer disposed over the surface of the first base body;
a base buffer layer disposed between the metal wiring layer and the first connection pad in a vertical direction and the base buffer layer including the first insulating material having the porous structure;
a via disposed in the base buffer layer and connecting the metal wiring layer to the first connection pad; and
a via barrier layer disposed between the via and the base buffer layer in a lateral direction and the via barrier layer including a two-dimensional material.

14. The semiconductor device of claim 1, wherein the second stacked structure further includes:
a metal wiring layer disposed over the surface of the second base body;
a base buffer layer disposed between the metal wiring layer and the second connection pad in a vertical direction and including the second insulating material having the porous structure;
a via disposed in the base buffer layer and connecting the metal wiring layer to the second connection pad; and
a via barrier layer disposed between the via and the base buffer layer in a lateral direction and the via barrier layer including a two-dimensional material.

15. The semiconductor device of claim 1, wherein the second stacked structure further includes:
a metal wiring layer disposed over the other surface opposite to the surface of the second base body;
a through via penetrating the second base body to connect the metal wiring layer to the second connection pad; and
a via barrier layer disposed between the second base body and the through via in a lateral direction and the via barrier layer including a two-dimensional material.

16. A semiconductor device comprising:
a first substrate structure that includes a substrate, a memory cell driver circuit disposed over the substrate, a first connection pad disposed over the substrate to be electrically connected to the memory cell driver circuit, and a first pad buffer layer disposed in a lateral direction of the first connection pad, the first pad buffer layer including a first insulating material having a porous structure;
a second substrate structure that includes a substrate, a memory cell structure disposed over the substrate, a second connection pad disposed over the substrate to be electrically connected to the memory cell structure, and a second pad buffer layer disposed in a lateral direction of the second connection pad, the second pad buffer layer including a second insulating material having a porous structure; and
a connection portion of the first and second substrate structures, that connects the first and second connection pads.

17. The semiconductor device of claim 16, wherein the first and second insulating materials having the porous structure comprise a metal-organic framework.

18. The semiconductor device of claim 17,
wherein the metal-organic framework of each of the first and second pad buffer layers has a two-dimensional structure including cavities, and
wherein each of the first and second pad buffer layers comprises at least one layer of the metal-organic framework.

19. The semiconductor device of claim 16, further comprising at least one of a first pad barrier layer disposed between the first connection pad and the first pad buffer layer, the first pad barrier layer including a two-dimensional material, and a second pad barrier layer disposed between the second connection pad and the second pad buffer layer, the second pad barrier layer including a two-dimensional material.

20. The semiconductor device of claim 19, wherein the two-dimensional material of each of the first and second pad barrier layers comprises MXene.

21. The semiconductor device of claim 20, wherein each of the first and second pad barrier layers comprises at least one layer of MXene.

22. The semiconductor device of claim 16,
wherein the first substrate structure further includes a first bonding dielectric layer disposed adjacent to the first connection pad in a lateral direction,
wherein the second substrate structure further includes a second bonding dielectric layer disposed adjacent to the second connection pad in a lateral direction, and
wherein the connection portion further includes bonding of the first bonding dielectric layer and the second bonding dielectric layer.

23. The semiconductor device of claim 16, wherein the first substrate structure further includes:
a driver circuit wiring disposed over the memory cell driver circuit;
a base buffer layer disposed between an uppermost wiring layer of the driver circuit wiring and the first connection pad in a vertical direction;
a via disposed in the base buffer layer and connecting the uppermost wiring layer to the first connection pad; and
a via barrier layer disposed between the via and the base buffer layer in a lateral direction and the via barrier layer including a two-dimensional material.

24. The semiconductor device of claim 16, wherein the second substrate structure further includes:
a cell wiring electrically connected to the memory cell structure;
a base buffer layer disposed between an uppermost wiring layer of the cell wiring and the second connection pad in a vertical direction;
a via disposed in the base buffer layer and connecting the uppermost wiring layer to the second connection pad; and
a via barrier layer disposed between the via and the base buffer layer in a lateral direction and the via barrier layer including a two-dimensional material.

25. A method of fabricating a semiconductor device, the method comprising:
forming a first substrate structure that includes a substrate, a first connection pad disposed over a surface of the first substrate, and a first pad buffer layer disposed adjacent to the first connection pad, the first pad buffer layer including a metal-organic framework;
forming a second substrate structure that includes a substrate, a second connection pad disposed over a surface of the second substrate, and a second pad buffer layer disposed adjacent to the second connection pad, the second pad buffer layer including a metal-organic framework; and
bonding the first and second substrate structures to each other to form a connection portion of the first and second connection pads.

26. The method of claim 25, wherein forming the first substrate structure includes:
providing the first substrate;
forming a metal wiring layer over the surface of the first substrate;
forming a base buffer layer including a metal-organic framework on the metal wiring layer;
forming a via disposed in the base buffer layer and connected to the metal wiring layer;
forming a via barrier layer disposed between the via and the base buffer layer and including MXene;
forming the first connection pad connected to the via over the base buffer layer; and
forming the first pad barrier layer and the first pad buffer layer that are disposed adjacent to the first connection pad over the base buffer layer.

27. The method of claim 26, further comprising forming a memory cell driver circuit or a memory cell structure over the first substrate.

28. The method of claim 25, wherein forming the second substrate structure includes:
providing the second substrate;
forming a metal wiring layer over the surface of the second substrate;
forming a base buffer layer including a metal-organic framework on the metal wiring layer;
forming a via disposed in the base buffer layer and connected to the metal wiring layer;
forming a via barrier layer disposed between the via and the base buffer layer and including MXene;
forming the second connection pad connected to the via over the base buffer layer; and
forming the second pad barrier layer and the second pad buffer layer that are disposed adjacent to the second connection pad over the base buffer layer.

29. The method of claim 25, wherein forming the second substrate structure includes:
forming a metal wiring layer over the other surface opposite to the surface of the second substrate;
forming a through via penetrating the second substrate and connected to the metal wiring layer;
forming a via barrier layer disposed between the via and the base buffer layer and including MXene;
forming the second connection pad connected to the via over the base buffer layer; and
forming the second pad barrier layer and the second pad buffer layer that are disposed adjacent to the second connection pad over the base buffer layer.

30. The method of claim 25,
wherein forming the first substrate structure further includes forming a first bonding dielectric layer disposed adjacent to the first connection pad in a lateral direction,
wherein forming the second substrate structure further includes forming a second bonding dielectric layer disposed adjacent to the second connection pad in a lateral direction, and
wherein bonding the first and second substrate structures to each other includes bonding the first and second connection pads to each other and bonding the first and second bonding dielectric layers to each other.

31. A semiconductor device comprising:
a first substrate structure that includes a first connection pad and a first pad buffer layer disposed to surround at least a sidewall of the first connection pad; and
a second substrate structure that includes a second connection pad and a second pad buffer layer disposed to surround at least a sidewall of the second connection pad,
wherein the first and second substrate structures are physically and electrically bonded to each other using the first and second connection pads, and
wherein the first and second pad buffer layers include an insulating material having a porous structure.

32. The semiconductor device of claim 31, wherein the insulating material having the porous structure comprises a metal-organic framework.

33. The semiconductor device of claim 32,
wherein the first substrate structure further includes a first pad barrier layer disposed between the first connection pad and the first pad buffer layer, the first pad barrier layer including a two-dimensional material, and
wherein the second substrate structure further includes a second pad barrier layer disposed between the second connection pad and the second pad buffer layer, the second pad barrier layer including a two-dimensional material.

34. The semiconductor device of claim 33, wherein the two-dimensional material comprises MXene.
